(19) United States
(12) Patent Application Publication
(10) Pub. No.: US 2024/0276748 A1
(43) Pub. Date: Aug. 15, 2024

(54) ELECTRONIC DEVICE AND METHOD OF PRODUCING ELECTRONIC DEVICE

(71) Applicant: SHARP KABUSHIKI KAISHA, Sakai City, Osaka (JP)

(72) Inventor: Yuma YAGUCHI, Sakai City, Osaka (JP)

(21) Appl. No.: 18/568,752

(22) PCT Filed: Aug. 6, 2021
(86) PCT No.: PCT/JP2021/029248

§ 371 Date: Dec. 8, 2023

(51) Int. Cl. H10K 50/115; H10K 59/12; H10K 59/35

(52) U.S. Cl. CPC H10K 50/115; H10K 59/1201; H10K 59/35

(57) ABSTRACT

An electronic device has a functional layer containing nanoparticles. The functional layer has: a main region; and an outer edge region formed on an outer edge of the functional layer and containing outer edge ligands. If the main region contains main ligands, the outer edge ligands are different from the main ligands. The outer edge ligands per unit volume contained in the outer edge region are greater in amount than the outer edge ligands per unit volume in the main region.

### TECHNICAL FIELD

The disclosure relates to an electronic device and a method of producing the electronic device.

### BACKGROUND ART

Patent Document 1 discloses a light-emitting element including a light-emitting layer containing quantum dots, and a method of producing the light-emitting element.

### CITATION LIST

### Patent Literature

[Patent Document 1] Japanese Unexamined Patent Application Publication No. 2009-087760

### SUMMARY

### Technical Problem

The light-emitting layer disclosed in Patent Document 1 and containing quantum dots might suffer reduction in light emission efficiency or decrease in emission lifetime because such a substance as water permeates the light-emitting layer at, for example, a rinsing step. Hence, a functional layer containing nanoparticles might suffer functional deterioration due to, for example, permeation of water.

### Solution to Problem

In order to solve the above problem, an electronic device according to an aspect of the present disclosure includes a functional layer containing nanoparticles. The functional layer has: an outer edge region formed on an outer edge of the functional layer and containing outer edge ligands; and a main region internally in contact with the outer edge region. The outer edge ligands per unit volume contained in the outer edge region are greater in amount than the outer edge ligands per unit volume in the main region.

Furthermore, in order to solve the above problem, a method of producing an electronic device according to an aspect of the present disclosure includes: a first functional layer depositing step of depositing a first functional layer containing first nanoparticles; a first resist layer depositing step of depositing a first resist layer above the first functional layer; a first light exposure step of exposing the first resist layer with light; a first developing step of developing the first resist layer to remove a portion of the first resist layer; and a first etching step of partially etching a surface of the first functional layer from toward the first resist layer to introduce first outer edge ligands, in order to form a first outer edge region on an outer edge that is at least a portion of the first functional layer, the first outer edge region having: the first outer edge ligands; and the first nanoparticles.

### Advantageous Effect of Invention

An aspect of the present disclosure keeps such substances as water from penetrating into a functional layer containing nanoparticles,

### BRIEF DESCRIPTION OF DRAWINGS

FIG. 1 illustrates a schematic cross-sectional view of a display device according to a first embodiment, and partially enlarged views of the cross-section.

FIG. 2 illustrates a schematic plan view of the display device according to the first embodiment.

FIG. 3 illustrates another partially enlarged view of the cross-section of the display device according to the first embodiment.

FIG. 4 is a flowchart showing a method of producing the display device according to the first embodiment.

FIG. 5 illustrates cross-sectional views of steps included in the steps of producing the display device according to the first embodiment.

FIG. 6 illustrates cross-sectional views of other steps included in the steps of producing the display device according to the first embodiment.

FIG. 7 illustrates cross-sectional views of yet other steps included in the steps of producing the display device according to the first embodiment.

FIG. 8 illustrates cross-sectional views of still other steps included in the steps of producing the display device according to the first embodiment.

FIG. 9 illustrates partially enlarged cross-sectional views of steps included in the steps of producing the display device according to the first embodiment.

FIG. 10 illustrates plan views of steps included in the steps of producing the display device according to the first embodiment.

FIG. 11 illustrates plan view of other steps included in the steps of producing the display device according to the first embodiment.

FIG. 12 is a flowchart showing a method of producing a display device according to a second embodiment.

FIG. 13 illustrates cross-sectional views of steps included in the steps of producing the display device according to the second embodiment.

FIG. 14 illustrates cross-sectional views of other steps included in the steps of producing the display device according to the second embodiment.

FIG. 15 is a flowchart showing a method of producing a display device according to a third embodiment.

FIG. 16 illustrates cross-sectional views of steps included in the steps of producing the display device according to the third embodiment.

FIG. 17 illustrates cross-sectional views of other steps included in the steps of producing the display device according to the third embodiment.

FIG. 18 is a schematic cross-sectional view of a display device according to a fourth embodiment.

FIG. 19 is a flowchart showing a method of producing the display device according to the fourth embodiment.

### DESCRIPTION OF EMBODIMENTS

### First Embodiment

### Outline of Display Device

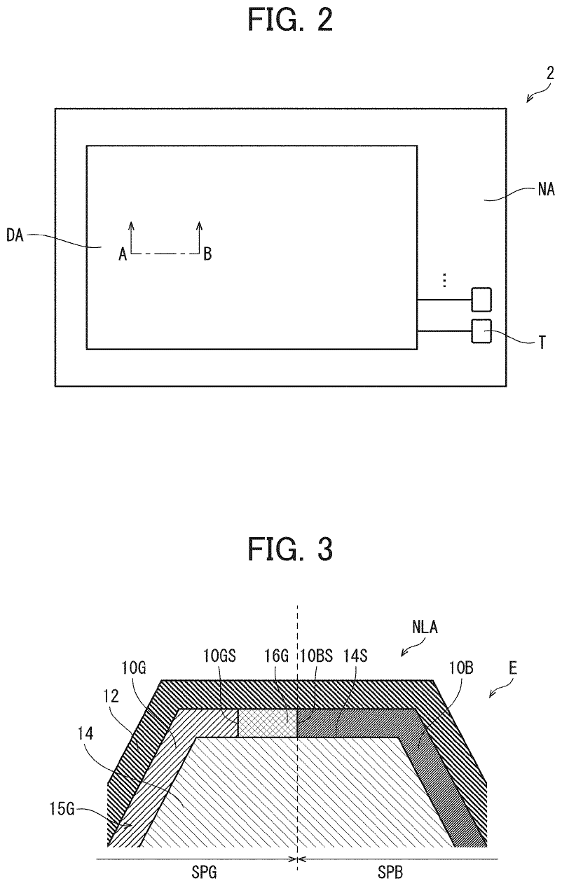

Described below as a first embodiment will a display device; that is, an embodiment of an electronic device. FIG. 2 is a schematic plan view of a display device 2 according to this embodiment. As illustrated in FIG. 2, the display device 2 according to this embodiment includes: a display region DA that releases light emitted from each of the subpixels in order to display an image; and a picture-frame region NA surrounding the display region DA. The subpixels will be described later. The picture-frame region NA includes terminals T formed to receive signals for driving the light-emitting elements of the display device 2.

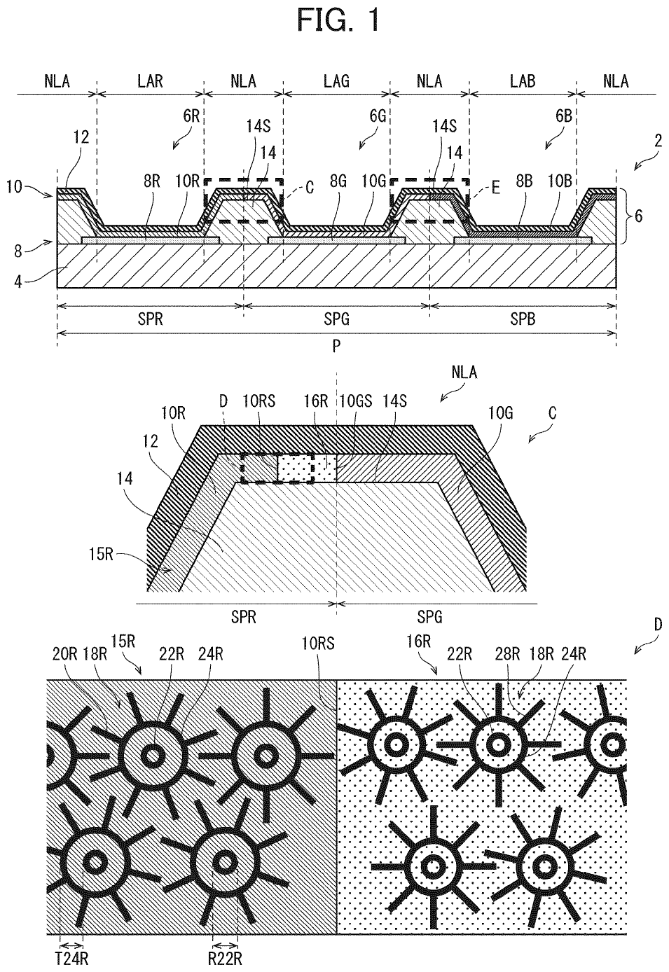

FIG. 1 illustrates a schematic cross-sectional view of the display device 2 according to this embodiment, and partially enlarged views of the cross-section. The schematic cross-sectional view of the display device 2 illustrated in FIG. 1 is taken along line A-B in FIG. 2.

The display device 2 according to this embodiment includes a plurality of pixels positioned to overlap with the display region DA in plan view. Furthermore, each of the plurality of pixels includes a plurality of subpixels. Each of the subpixels contains a functional layer, and the functional layer contains nanoparticles. The subpixel represents a range in which kinds of the nanoparticles (e.g., quantum dots) contained in the functional layer are different from one another. The schematic cross-sectional view of the display device 2 in FIG. 1 illustrates a pixel P among the plurality of pixels included in the display device 2. In particular, the pixel P includes: a red subpixel SPR, a green subpixel SPG, and a blue subpixel SPB.

As illustrated in FIG. 1, the display device 2 according to this embodiment includes a light-emitting element layer 6 above a substrate 4. In particular, the display device 2 has a structure in which the layers in the light-emitting element layer 6 are stacked on top of another above the substrate 4 including not-shown thin-film transistors (TFTs). Note that, in Description, the direction from a light-emitting layer 10 toward a pixel electrode 8 of the light-emitting element layer 6 is referred to as a “downward direction”, and the direction from the light-emitting 15 layer 10 toward a common electrode 12 of the light-emitting element layer 6 is referred to as an “upward direction”. The light-emitting element layer 6 will be described later.

### Outline of Light-Emitting Element

The light-emitting element layer 6 includes: the pixel electrode 8 serving as a first electrode; the light-emitting layer 10 serving as a functional layer; and the common electrode 12 serving as a second electrode, all of which are provided in the stated order from toward the substrate 4. In other words, the light-emitting element layer 6 includes the light-emitting layer 10 between the pixel electrode 8 and the common electrode 12. The functional layer contains nanoparticles, and the nanoparticles are, for example, quantum dots. The pixel electrode 8 of the light-emitting element layer 6 is formed above the substrate 4. The pixel electrode 8 is shaped into an island, provided for each of the subpixels, and electrically connected to a respective TFT of the substrate 4. For example, the pixel electrode 8 is an anode, and the common electrode 12 is a cathode. Note that the display device 2 may be provided with a not-shown sealing layer provided above the light-emitting element layer 6 and sealing the light-emitting element layer 6.

In this embodiment, the light-emitting element layer 6 includes a plurality of light-emitting elements. In particular, one light-emitting element is provided for each of the subpixels. In this embodiment, for example, the light-emitting element layer 6 includes, as the light-emitting elements, a red light-emitting element 6R in the red subpixel SPR, a green light-emitting element 6G in the green subpixel SPG, and a blue light-emitting element 6B in the blue subpixel SPB. Hereinafter, in Description, unless otherwise described, the term “light-emitting element” refers to any one of the red light-emitting element 6R, the green light-emitting element 6G, and the blue light-emitting element 6B included in the light-emitting element layer 6.

Here, the pixel electrode 8 and the light-emitting layer 10 are formed individually for each of the subpixels. In particular, in this embodiment, the pixel electrode 8 includes: a pixel electrode 8R for the red light-emitting element 6R; a pixel electrode 8G for the green light-emitting element 6G; and a pixel electrode 8B for the blue light-emitting element 6B. Furthermore, the light-emitting layer 10 includes: a red light-emitting region LAR for the red light-emitting element 6R; a green light-emitting region LAG for the green light-emitting element 6G; and a blue light-emitting region LAB for the blue light-emitting element 6B. On the other hand, the common electrode 12 is formed in common to the plurality of subpixels.

Hence, in this embodiment, the red light-emitting element 6R includes: the pixel electrode 8R; the red light-emitting region LAR; and the common electrode 12. Furthermore, the green light-emitting element 6G includes: the pixel electrode 8G; the green light-emitting region LAG; and the common electrode 12. Moreover, the blue light-emitting element 6B includes: the pixel electrode 8B; the blue light-emitting region LAB; and the common electrode 12.

In this embodiment, the red light-emitting region LAR glows red, and includes a red light-emitting layer 10R that emits a red light. The green light-emitting region LAG glows green, and includes a green light-emitting layer 10G that emits a green light. The blue light-emitting region LAB glows blue, and includes a blue light-emitting layer 10B that emits a blue light. In other words, the red light-emitting element 6R, the green light-emitting element 6G, and the blue light-emitting element 6B respectively emit a red light, a green light, and a blue light. Furthermore, in other words, the light-emitting layer 10 includes, as multiple kinds of light-emitting regions emitting light in different colors, the red light-emitting region LAR that emits a red light, the green light-emitting region LAG that emits a green light, and the blue light-emitting region LAB that emits a blue light.

Here, the blue light has a center wavelength in a wavelength band of, for example, 400 nm or more and 500 nm or less. Furthermore, the green light has a center wavelength in a wavelength band of, for example, more than 500 nm and 600 nm or less. Moreover, the red light has a center wavelength in a wavelength band of, for example, more than 600 nm and 780 nm or less.

Note that the light-emitting element layer 6 according to this embodiment shall not be limited to the above configuration, and may further include another layer in addition to the functional layer between the pixel electrode 8 and the common electrode 12. For example, the light-emitting element layer 6 may further include, in addition to the light-emitting layer 10, at least one of a hole injection layer or a hole transport layer serving as a functional layer between the pixel electrode 8 and the light-emitting layer 10. In addition, the light-emitting element layer 6 may further include at least one of an electron transport layer or an electron injection layer between the light-emitting layer 10 and the common electrode 12.

When the light-emitting element layer 6 includes any one of the hole injection layer, the hole transport layer, the electron transport layer, or the electron injection layer as a functional layer serving as a charge transport layer, the charge transport layer may contain quantum dots as nanoparticles. In this case, each of the quantum dots contained in the charge transport layer may have a core-shell structure including: a core; and a shell coating the core, or may have a structure of a core alone. The core-shell structure will be described later. Furthermore, the charge transport layer may contain, as the quantum dots, nanoparticle semiconductor containing, for example, ZnO, NiO, or CuO. Moreover, ligands may be coordinated to the quantum dots contained in the charge transport layer.

The pixel electrode 8 and the common electrode 12 contain conductive materials, and are electrically connected to the light-emitting layer 10. Of the pixel electrode 8 and the common electrode 12, the electrode closer to a display surface of the display device 2 is a translucent electrode.

The pixel electrode 8 is formed of, for example: a Ag—Pd—Cu alloy; and indium tin oxide (ITO) stacked on the Ag—Pd—Cu alloy. The pixel electrode 8 having this configuration is, for example, a reflective electrode reflective to light emitted from the light-emitting layer 10. Hence, of the light emitted from the light-emitting layer 10, light traveling in the downward direction is reflected off the pixel electrode 8.

Whereas, the common electrode 12 is formed of, for example, a translucent Mg—Ag alloy. In other words, the common electrode 12 is a transparent electrode transparent to light emitted from the light-emitting layer 10. Hence, of the light emitted from the light-emitting layer 10, light traveling in the upward direction passes through the common electrode 12. Thus, the display device 2 can emit the light from the light-emitting layer 10 in the upward direction.

As described above, the display device 2 can direct both of the lights, the light emitted from the light-emitting layer 10 in the upward direction and the light emitted from the light-emitting layer 10 in the downward direction, toward the common electrode 12 (in the upward direction). That is, the display device 2 is a top-emission display device.

Furthermore, in this embodiment, the common electrode 12, which is a translucent electrode, partially reflects the light emitted from the light-emitting layer 10. In this case, a cavity for the light emitted from the light-emitting layer 10 may be formed between the pixel electrode 8, which is a reflective electrode, and the common electrode 12, which is a translucent electrode. The cavity formed between the pixel electrode 8 and the common electrode 12 can improve chromaticity of the light emitted from the light-emitting layer 10.

Note that the configurations of the pixel electrode 8 and the common electrode 12 described above are merely examples, and the pixel electrode 8 and the common electrode 12 may have other configurations. For example, the electrode close to the display surface of the display device 2 may be an anode. In this case, the anode may be a translucent electrode, and the cathode may be a reflective electrode. Thanks to such a feature, the display device 2 can direct both of the lights, the light emitted from the light-emitting layer 10 in the upward direction and the light emitted from the light-emitting layer 10 in the downward direction, toward the anode (in the downward direction). That is, the display device 2 may be a bottom-emission display device.

The light-emitting layer 10 emits light by recombination of holes transported from the anode and electrons transported from the cathode. Details of the material contained in the light- emitting layer 10 will be described later.

Note that the display device 2 according to this embodiment includes a light-emitting element including the anode provided toward the substrate 4. However, the display device 2 may have any given configuration. For example, the light-emitting element layer 6 included in the display device 2 according to this embodiment may include: the cathode; the light-emitting layer 10; and the anode, all of which are stacked on top of another in the stated order from toward the substrate 4. In this case, the cathode is a pixel electrode shaped into an island for each of the subpixels, and the anode is a common electrode formed in common to the plurality of subpixels.

The display device 2 according to this embodiment further includes a bank 14 on the substrate 4. In plan view, the bank 14 is formed in a position across a boundary between subpixels adjacent to each other. In particular, the pixel electrode 8 is divided by the bank 14 into: the pixel electrode 8R, the pixel electrode 8G; and the pixel electrode 8B. A region overlapping with the bank 14 in plan view is a non-light-emitting region NLA; that is, a region not intended to emit light. Note that, as illustrated in FIG. 1, the bank 14 may be formed in a position for covering each of the peripheral end portions of the pixel electrode 8.

In this embodiment, each bank 14 has an upper surface 14S toward the common electrode 12. Here, in this embodiment, each bank 14 is formed so that the upper surface 14S is provided across a boundary between subpixels adjacent to each other. Thus, the bank 14 separates subpixels that emit light in different colors.

### Outer Edge Region

A configuration of the light-emitting layer 10 on an outer surface of the bank 14 including the upper surface 14S will be described, with reference to a partially enlarged view of the cross-section of the display device 2 in FIG. 1. In the schematic cross-sectional view of the display device 2 illustrated in FIG. 1, a region C in FIG. 1 is positioned near the upper surface 14S of the bank 14 positioned across a boundary between the red subpixel SPR and the green subpixel SPG. Furthermore, the region C in FIG. 1 is positioned to overlap with the bank 14 in plan view, and included in the non-light-emitting region NLA.

At least one functional layer in the display device 2 has: a main region; and an outer edge region formed on an outer edge of the functional layer. In other words, the main region is internally in contact with the outer edge region. The main region contains main ligands, and the outer edge region contains outer edge ligands different in properties from the main ligands. Here, the term “different in properties” means, for example, different in solubilities in a polar solvent. For example, a statement “two kinds of ligands have different properties from each other” means that one kind of ligands are soluble in a polar solvent, and the other kind of ligands are insoluble in a polar solvent. That is, the polarities of the ligands are different from each other.

The main region does not preferably contain the outer edge ligands; however, the main region may contain the outer edge ligands. At least, the outer edge ligands per unit volume contained in the outer edge region are greater in amount than the outer edge ligands per unit volume in the main region. Furthermore, the outer edge region may or may not contain the main ligands. The main ligands per unit volume contained in the main region are greater in amount than the main ligands per unit volume in the outer edge region.

On the outer surface of the bank 14 illustrated in the enlarged view of the region C in FIG. 1, the red light-emitting layer 10R and the green light-emitting layer 10G are formed. Here, the red light-emitting layer 10R has: a red first main region 15R; and a red first outer edge region 16R formed adjacent to a side surface 10RS of an end portion of the red first main region 15R toward the green light-emitting layer 10G. Furthermore, the red first outer edge region 16R is formed on the upper surface 14S of the bank 14, and brought into contact with a side surface 10GS of an end portion of the green light-emitting layer 10G toward the red light-emitting layer 10R. Note that because the red first outer edge region 16R is formed on the upper surface 14S of the bank 14, the red first outer edge region 16R is formed in a position overlapping with the bank 14 in plan view of the light-emitting layer 10.

### (Main Light-Emitting Material)

The red first main region 15R and the red first outer edge region 16R will be further described, with reference to another partially enlarged view of the cross-section of the display device 2 illustrated in FIG. 1. A region D illustrated in FIG. 1 is included in the region C, brought into contact with the red first outer edge region 16R, and positioned near the side surface 10RS of the red first main region 15R.

As seen in the enlarged view of the region D in FIG. 1, the red first main region 15R contains, as a main light-emitting material, red quantum dots 18R coordinated with red main ligands 20R. In this embodiment, holes from the pixel electrode 8 and electrons from the common electrode 12 are injected into the red quantum dots 18R coordinated with the red main ligands 20R. The holes and the electrons recombine together to form an exciton. Furthermore, the red quantum dots 18R coordinated with the red main ligands 20R are excited by the formed exciton, and emit a red light.

Each of the red quantum dots 18R has a structure commonly referred to as a core-shell structure including, for example: a core 22R; and a shell 24R serving as a main shell coating a periphery of the core 22R. In the red quantum dot 18R, the recombination of the electrons and the holes and generation of the red light occur mainly in the core 22R. The shell 24R has functions of reducing such a problem as development of a defect in the core 22R or generation of dangling bonds, and reducing recombination of carriers through a deactivation process. In this case, the red main ligands 20R are coordinated to an outer surface of the shell 24R.

As to the red quantum dot 18R, the materials of the core 22R and the shell 24R may contain materials to be used as a core material and a shell material of a quantum dot having a known core-shell structure. Furthermore, in this embodiment, the core 22R has a diameter R22R, and the shell 24R has a thickness T24R. Moreover, the red main ligands 20R may contain a material used for known ligands and having a function of reducing agglomeration of the red quantum dots 18R.

Whereas, as illustrated in the enlarged view of the region D in FIG. 1, the red first outer edge region 16R contains: the plurality of red quantum dots 18R; and red first outer edge ligands 28R serving as outer edge ligands that are coordinated to each of the red quantum dots 18R.

In this embodiment, the red main ligands 20R of the red first main region 15R and the red first outer edge ligands 28R of the red first outer edge region 16R are different from each other. For example, the red main ligands 20R are soluble in nonpolar solvents; in other words, insoluble in polar solvents, and the red first outer edge ligands 28R are soluble in polar solvents including water; in other words, insoluble in nonpolar solvents. Furthermore, for example, the red quantum dots 18R coordinated with the red main ligands 20R are insoluble in nonpolar solvents, and the red quantum dots 18R coordinated with the red first outer edge ligands 28R are soluble in polar solvents.

The red quantum dots 18R coordinated with the red first outer edge ligands 28R are shorter in emission lifetime, or lower in light emission efficiency in relation to density of injected carriers, than the red quantum dots 18R coordinated with the red main ligands 20R. Furthermore, the red quantum dots 18R coordinated with the red first outer edge ligands 28R do not have to emit light. In other words, the red quantum dots 18R coordinated with the red first outer edge ligands 28R may have no emission lifetime.

As described above, the light-emitting layer 10 according to this embodiment includes the red light-emitting layer 10R serving as a functional layer. The red light-emitting layer 10R includes: the red first main region 15R serving as a main region; and the red first outer edge region 16R serving as an outer edge region. In DESCRIPTION, the main region is a region capable of mainly exhibiting the main function of the functional layer, and the red light-emitting layer 10R is formed in a light-emitting region that mainly glow red. Furthermore, the main region may be formed in the non-light-emitting region NLA. The outer edge region is a region formed on an outer edge of the red light-emitting layer 10R serving as a functional layer. The outer edge region mainly contains as ligands outer edge ligands different from the main ligands mainly contained in the main region. The outer edge ligands in the red light-emitting layer 10R are formed in the non-light-emitting region NLA.

### Another Example of Outer Edge Region

Another configuration of the light-emitting layer 10 on the outer surface of the bank 14 will be described, with reference to another partially enlarged view of the cross-section of the display device 2 in FIG. 3. A region E in FIG. 3 is seen in the schematic cross-sectional view of the display device 2 illustrated in FIG. 1. The region E is positioned near the upper surface 14S of the bank 14 positioned across a boundary between the green subpixel SPG and the blue subpixel SPB.

On the outer surface of the bank 14 illustrated in the enlarged view of the region E in FIG. 3, the green light-emitting layer 10G and the blue light-emitting layer 10B are formed. The green light-emitting layer 10G includes: a green first main region 15G; and a green first outer edge region 16G. Here, the green first outer edge region 16G is formed adjacent to a side surface 10GS of an end portion of the green first main region 15G toward the blue light-emitting layer 10B. Furthermore, the green first outer edge region 16G is formed on the upper surface 14S of the bank 14, and brought into contact with a side surface 10BS of an end portion of the blue light-emitting layer 10B toward the green light-emitting layer 10G.

The green light-emitting layer 10G contains a main light-emitting material that emits a green light. The green light-emitting layer 10G contains, as the main light-emitting material, green quantum dots coordinated with green main ligands.

The green first outer edge region 16G contains green quantum dots that are: different from the green quantum dots contained in the green light-emitting layer 10G and coordinated with the green main ligands; and coordinated with green first outer edge ligands. Similar to, for example, the red first outer edge region 16R, the green first outer edge region 16G may contain green quantum dots that are: coordinated with the green first outer edge ligands; and shorter in emission lifetime, or lower in light emission efficiency, than the green quantum dots coordinated with the green main ligands.

### Advantageous Effects of Display Device

The red light-emitting region LAR of the red light-emitting layer 10R has the red quantum dots 18R coordinated with the red main ligands 20R. In addition, the red light-emitting layer 10R includes the red first outer edge region 16R: positioned on the outer edge of the red light-emitting layer 10R; and having the red quantum dots 18R coordinated with the red first outer edge ligands 28R different from the red main ligands 20R.

A functional layer containing nanoparticles might suffer functional deterioration due to, for example, permeation of water into the functional layer. For example, the red light-emitting layer 10R might come into contact with water either at a production step or because of partial breakage of the display device. As a result, the red light-emitting layer 10R could suffer reduction in light emission efficiency or decrease in emission lifetime. However, as to the red light-emitting layer 10R according to this embodiment, the red first outer edge region 16R keeps water from permeating from the outer edge of the red light-emitting layer 10R into the red first main region 15R. Thus, the red light-emitting layer 10R can protect the red light-emitting region LAR from water, curb functional deterioration of the red light-emitting layer 10R, and avoid reduction in light emission efficiency or decrease in emission lifetime.

Specifically, for example, suppose the red quantum dots 18R coordinated with the red main ligands 20R are soluble in a polar solvent. If the red first main region 15R comes into contact with water, the water might permeate the entire red first main region 15R. As a result, the red light-emitting layer 10R could suffer reduction in light emission efficiency or decrease in emission lifetime. However, in this embodiment, the red first outer edge region 16R contains the red quantum dots 18R coordinated with the red first outer edge ligands 28R and insoluble in a polar solvent, unlike the red quantum dots 18R coordinated with the red main ligands 20R. In this case, even if the red light-emitting layer 10R comes into contact with water at the outer edge of the red light-emitting layer 10R, the red first outer edge region 16R keeps the red first main region 15R from coming into contact with water, thereby successfully avoiding reduction in light emission efficiency or decrease in emission lifetime of the red light-emitting layer 10R.

Furthermore, even if the red quantum dots 18R coordinated with the red main ligands 20R are insoluble in a polar solvent, water might permeate the entire red first main region 15R if the red first main region 15R comes into contact with the water. However, the red first outer edge region 16R contains the red quantum dots 18R coordinated with the red first outer edge ligands 28R soluble in a polar solvent. Thanks to such a feature, the water is held on the outer edge of the red light-emitting layer 10R, such that the water is less likely to permeate the entire red first main region 15R, thereby successfully avoiding reduction in light emission efficiency, or decrease in emission lifetime, of the red light-emitting layer 10R.

Likewise, also as to the green light-emitting layer 10G, the green first outer edge region 16G keeps water from permeating from the outer edge of the green light-emitting layer 10G into the green first main region 15G. Thus, the green light-emitting layer 10G can protect the green light-emitting region LAG from water, curb functional deterioration of the green light-emitting layer 10G, and avoid reduction in light emission efficiency or decrease in emission lifetime.

Note that, in this embodiment, the blue light-emitting layer 10B may include only the main region. In other words, in the light-emitting layer 10 of the display device 2 according to this embodiment, at least one of the plurality of light-emitting layers may have a main region and an outer edge region formed on an outer edge end portion of the light-emitting layer.

In the above case, the light-emitting layer 10 includes three kinds of light-emitting layers that emit light in different colors; that is, the red light-emitting layer 10R, the green light-emitting layer 10G, and the blue light-emitting layer 10B. Furthermore, in the light-emitting layer 10, only two kinds of the light-emitting layers; that is, the red light-emitting layer 10R and the green light- emitting layer 10G each include a main region and an outer edge region.

Note that the light-emitting layer 10 includes: the red light-emitting layer 10R having the red light-emitting region LAR; the green light-emitting layer 10G having the green light-emitting region LAG; and the blue light-emitting layer 10B having the blue light-emitting region LAB. However, in addition to the three kinds of light-emitting layers, the light-emitting layer 10 may further include other light-emitting layers including a yellow light-emitting layer having a yellow light-emitting region for emitting a yellow light. For example, the light-emitting layer 10 may include n kinds of light-emitting regions that emit light in different colors, where n is a natural number of 2 or more. Only the (n−1) kinds of light-emitting regions may each include a main region and an outer edge region.

Note that, in this embodiment, each of the red light-emitting layer 10R and the green light-emitting layer 10G of the display device 2 includes a main region and an outer edge region. However, this embodiment shall not be limited to such a case. For example, among the light-emitting layers included in the display device 2, only the red light-emitting layer 10R may include a main region and an outer edge region, and the green light-emitting layer 10G may include only the green first main region 15G serving as a main region.

### Details of Main Light-Emitting Materials

In this embodiment, the red main ligands 20R in the red first main region 15R and the red first outer edge ligands 28R in the red first outer edge region 16R are different from each other. Hence, the display device 2 according to this embodiment can more efficiently provide the red first outer edge region 16R with a function different from the function of the red first main region 15R, depending on differences between the contained ligands.

For example, in this embodiment, the red quantum dots 18R coordinated with the red main ligands 20R may be soluble in a nonpolar solvent, and the red quantum dots 18R coordinated with the red first outer edge ligands 28R may be soluble in a polar solvent. If the red quantum dots 18R coordinated with the red first outer edge ligands 28R are soluble in a polar solvent, the red quantum dots 18R can hold at least some of water permeating from toward the red first outer edge region 16R into the red light-emitting layer 10R. Thus, when the red quantum dots 18R coordinated with the red first outer edge ligands 28R are soluble in a polar solvent, the red light-emitting layer 10R can reduce permeation of water into the red first main region 15R. Such a feature reduce permeation of water into the red first main region 15R, and deterioration of a main light-emitting material of the red light-emitting layer 10R.

For example, suppose the red quantum dots 18R coordinated with the red main ligands 20R are soluble in a nonpolar solvent. In this case, the red main ligands 20R may be ligands that contain, as a coordinating functional group, at least one selected from the group consisting of a thiol group, an amino group, a carboxyl group, a phosphonic group, a phosphine group, and a phosphine oxide group.

Examples of the ligands having one thiol group as the coordinating functional group include thiol-based ligands such as octadecanethiol, hexanedecanethiol, tetradecanethiol, dodecanethiol, decanethiol, and octanethiol.

Examples of the ligands having one amino group as the coordinating functional group include primary-amine-based ligands such as oleylamine, stearyl (octadecyl) amine, dodecyl (lauryl) amine, decylamine, and octylamine.

Examples of the ligands having one carboxyl group as the coordinating functional group include fatty-acid-based ligands such as oleic acid, stearic acid, palmitic acid, myristic acid, lauryl (dodecane) acid, decanoic acid, and octanoic acid.

Examples of the ligands having one phosphonic group as the coordinating functional group include phosphonic-acid-based ligands such as hexadecylsulfonic acid.

Examples of the ligands having one phosphine group as the coordinating functional group include phosphine-based ligands such as trioctylphosphine, triphenylphosphine, and tributylphosphine.

Examples of the ligands having one phosphine oxide group as the coordinating functional group include phosphine-oxide-based ligands such as trioctylphosphine oxide, triphenylphosphine oxide, and tributylphosphine oxide.

If the red quantum dots 18R coordinated with the red main ligands 20R are soluble in a nonpolar solvent, the red quantum dots 18R coordinated with the red first outer edge ligands 28R are soluble in, for example, a polar solvent. In this case, the red first outer edge ligands 28R may contain at least one selected from the group consisting of tetramethylammonium hydroxide (TMAH), 2-aminoethanethiol hydrochloride, 2-methaneaminoethanethiol hydrochloride, 2-ethaneaminoethanethiol hydrochloride, 2-dimethylaminoethanethiol hydrochloride, 2-methylethylaminoethanethiol hydrochloride, and 2-diethylaminoethanethiol hydrochloride. Furthermore, the red first outer edge ligands 28R may contain inorganic ligands (e.g., S2-, Cl-, Br-, I-, and F-based ligands) dispersible in a highly polar solvent.

Whereas, the red quantum dots 18R coordinated with the red main ligands 20R may be soluble in a polar solvent, and the red quantum dots 18R coordinated with the red first outer edge ligands 28R may be soluble in a nonpolar solvent. In this case, the red main ligands 20R are the same as the red first outer edge ligands 28R observed when, for example, the red quantum dots 18R coordinated with the red first outer edge ligands 28R are soluble in a polar solvent. Moreover, in such a case, the red first outer edge ligands 28R are the same as the red main ligands 20R observed when, for example, the red quantum dots 18R coordinated with the red main ligands 20R are soluble in a nonpolar solvent.

Note that this embodiment describes a case where each of the red light-emitting layer 10R, the green light-emitting layer 10G, and the blue light-emitting layer 10B contains an inorganic quantum-dot material as the main light-emitting material. However, this embodiment shall not be limited to such a case. Each of the red light-emitting layer 10R, the green light-emitting layer 10G, and the blue light-emitting layer 10B may contain an organic light-emitting material as the main light-emitting material.

In this case, each of the red first outer edge region 16R and the green first outer edge region 16G may contain a first organic material that is an altered product of the organic light-emitting material contained in each of the red light-emitting layer 10R and the green light-emitting layer 10G. Note that the altered product of the organic light-emitting material includes either a material in which some of the elements of the organic light-emitting material are substituted, or an oxide of the organic light-emitting material.

### Outline of Method of Producing Display Device

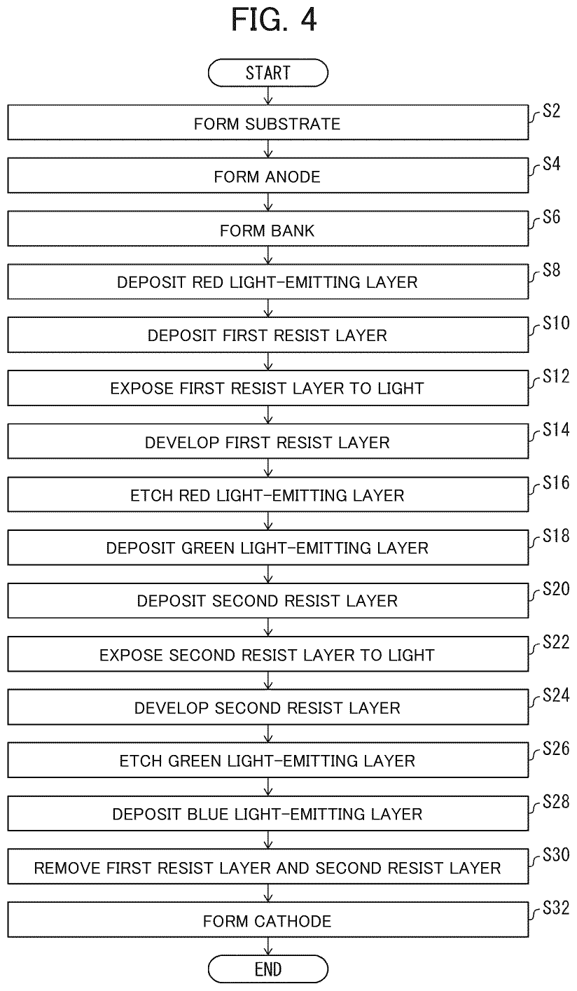

A method of producing the display device 2 according to this embodiment will be described, with reference to FIG. 4. FIG. 4 is a flowchart showing the method of producing the display device 2 according to this embodiment. Note that the display device 2 according to the modification described above can be produced by the same technique employed for producing the display device 2 according to this embodiment.

In the method of producing the display device 2 according to this embodiment, first, the substrate 4 is formed (Step S2). In forming the substrate 4, TFTs are formed in a glass substrate in association with the positions of the subpixels for the display device 2.

Next, the pixel electrode 8 is formed (Step S4). The pixel electrode 8 may be formed as described above. For example, a conductive material may be deposited in common to the subpixels by such a technique as sputtering. After that, a thin film of the conductive material may be patterned for each of the subpixels to form the pixel electrode 8.

Next, the bank 14 is formed (Step S6). The bank 14 may be formed of, for example, a resin material containing a photosensitive material. The resin material may be applied to the substrate 4 and the pixel electrode 8, and, after that, patterned by photolithography to form the bank 14.

### Depositing and Etching Light-Emitting Layer

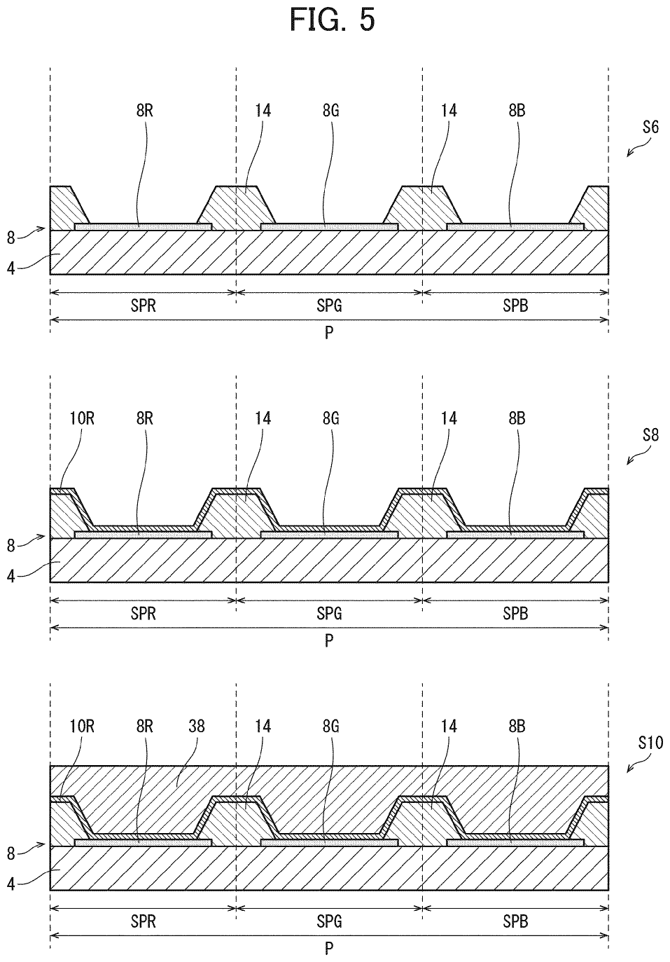

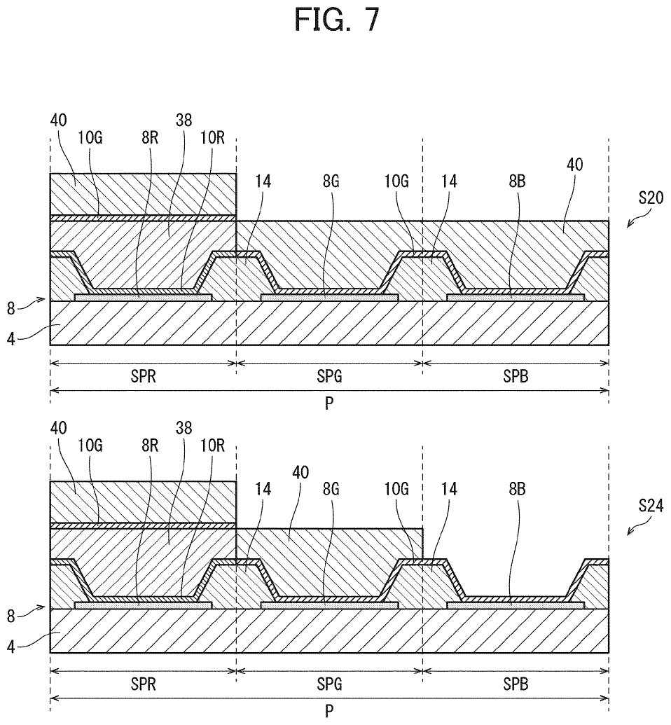

Each of the steps after Step S6 in the method of producing the display device 2 according to this embodiment will be described in more detail with reference to FIGS. 5 to 8. FIGS. 5 to 8 illustrate cross-sectional views of some of the steps of producing the display device 2 according to this embodiment. Note that, unless otherwise described, the cross-sectional views for DESCRIPTION, including FIGS. 5 to 8, illustrate cross-sections positionally corresponding to the cross-section of the display device 2 illustrated in FIG. 1.

The steps are carried out up to Step S6, such that, as illustrated at Step S6 in FIG. 5, a structure is formed to include the pixel electrode 8 and the bank 14 on the substrate 4. Note that the pixel electrode 8 includes the pixel electrode 8R for the red subpixel SPR, the pixel electrode 8G for the green subpixel SPG, and the pixel electrode 8B for the blue subpixel SPB as pixel electrodes each shaped into an island. The pixel electrodes 8R, 8G, and 8B are formed of a conductive material and patterned for the respective subpixels. Furthermore, the bank 14 is formed in a position for covering a boundary between the subpixels and an outer peripheral end portion of each of the pixel electrodes 8.

In the method of producing the display device 2 according to this embodiment, the bank 14 is formed, and, after that, the red light-emitting layer 10R is deposited (Step S8). Step S8 is a first functional layer depositing step of depositing a first functional layer (the red light-emitting layer 10R) containing the first main ligands (the red main ligands 20R) and first nanoparticles (the red quantum dots 18R). The red light-emitting layer 10R is formed in common to the plurality of subpixels. The red light-emitting layer 10R may be deposited by, for example, application.

Next, on the red light-emitting layer 10R, a first resist layer 38 is deposited (Step S10). Step S10 is a first resist layer depositing step of depositing the first resist layer 38 above the first functional layer (the red light-emitting layer 10R). The first resist layer 38 according to this embodiment contains a photosensitive resin material. In particular, the first resist layer 38 is a positive photoresist whose solubility in a specific developing solution increases when irradiated with, for example, an ultraviolet ray. The first resist layer 38 dissolves in an alkaline solvent when irradiated with, for example, an ultraviolet ray. The first resist layer 38 is formed of, for example, a solution containing a photosensitive resin material. The solution is applied to the red light-emitting layer 10R to form the first resist layer 38.

Furthermore, the first resist layer 38 may be soluble in a specific solvent, with or without exposure to light. For example, the first resist layer 38 may be soluble in propyleneglycol monomethyl ether acetate (PGMEA). In addition, the first resist layer 38 may be a negative photoresist that acquires insolubility in a specific developing solution when irradiated with an ultraviolet ray.

Next, the first resist layer 38 is exposed to light (Step S12). Step S12 is a first light exposure step of exposing the first resist layer 38 with light. At Step S12, the first light exposure step is carried out as, for example, a preliminary step of removing a portion of the first resist layer 38. The first exposure step involves irradiating only a portion of the first resist layer 38 with an ultraviolet ray, using, for example, a photomask.

Next, the first resist layer 38 is developed (Step S14). Step S14 is a first developing step of developing the first resist layer 38. Step S14 involves, for example, rinsing the first resist layer 38 with a specific developing solution to remove a portion of the first resist layer 38.

In this embodiment, Step S14 involves removing only the portion, of the first resist layer 38, formed in a position overlapping with the green subpixel SPG and the blue subpixel SPB. Hence, when Step S14 is completed, the red light-emitting layer 10R is exposed in the position overlapping with the green subpixel SPG and the blue subpixel SPB.

Next, a first etching step is carried out to partially etch a surface of the red light-emitting layer 10R from toward the first resist layer 38 (Step S16). The first etching step involves rinsing the red light-emitting layer 10R exposed from the first resist layer 38 with, for example, a first etchant in which the red light-emitting layer 10R is soluble.

The first etching step involves etching only the red light-emitting layer 10R positioned to overlap with the green subpixel SPG and the blue subpixel SPB and exposed from the first resist layer 38. Hence, Step S16 involves removing the red light-emitting layer 10R formed in a position overlapping with the green subpixel SPG and the blue subpixel SPB.

The first etchant contains, for example: the red first outer edge ligands 28R; and water as a solvent. If the red main ligands 20R are soluble in a nonpolar solvent and the red first outer edge ligands 28R are soluble in a polar solvent, the red main ligands 20R in the red first main region 15R are substituted with the red first outer edge ligands 28R when brought into contact with the first etchant. Thus, the red light-emitting layer 10R becomes soluble in water, and the red light-emitting layer 10R substituted with the red first outer edge ligands 28R is removed with the first etchant.

### Step of Forming Outer Edge Region

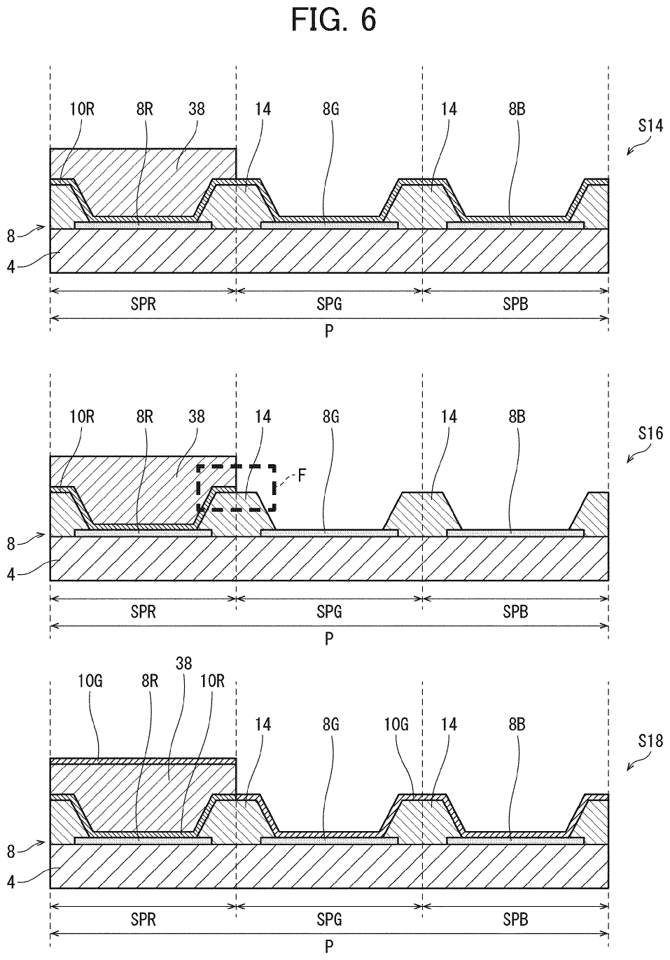

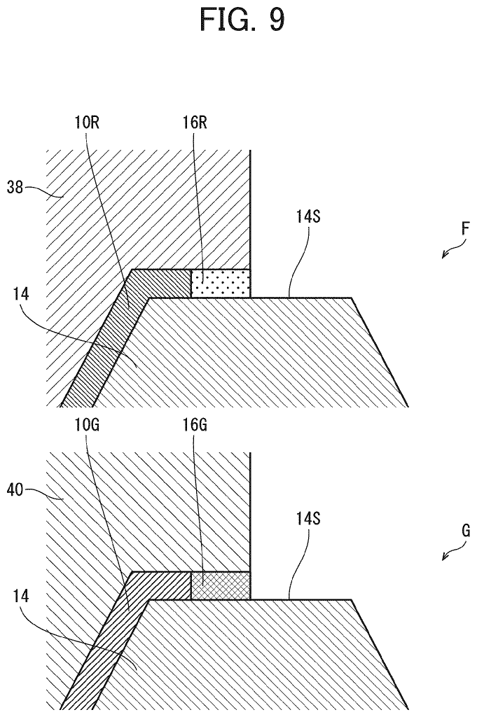

FIG. 9 illustrates enlarged cross-sectional views of the display device 2 according to this embodiment at a production step. A region F in FIG. 9 is an exemplary enlarged view of a region F at Step S16 in FIG. 6. At Step S14, an end surface included in the red light-emitting layer 10R and exposed from the first resist layer 38 touches the first etchant. Thus, ligands, which are coordinated to the quantum dots contained in an outer edge of the red light-emitting layer 10R including the end surface, are substituted with ligands different from the ligands coordinated to the quantum dots contained in the red light-emitting layer 10R. Hence, the red first outer edge ligands 28R are introduced into the outer edge of the red light-emitting layer 10R.

The red light-emitting layer 10R in which the ligands are substituted with the red first outer edge ligands 28R overlaps with the first resist layer 38, such that, at Step S16, at least a portion of the red light-emitting layer 10R is not removed. Hence, at Step S16, the ligands in the outer edge of the red light-emitting layer 10R are substituted and left on the upper surface 14S of the bank 14. This is how the red first outer edge region 16R is formed. In other words, the first etching step includes forming the first outer edge region, which has the first outer edge ligands different from the main ligands, on the outer edge that is at least a portion of the red light-emitting layer 10R. Furthermore, in forming the red first outer edge region 16R, the outer edge of the red light-emitting layer 10R exposed from the first resist layer 38 may be partially removed with the first etchant.

The first etchant contains, for example: a resist dissolving component to dissolve the first resist layer exposed to light; the first outer edge ligands; and a solvent in which a solute containing the first outer edge ligands dissolves. At the first etching step, for example, the first outer edge ligands may be coordinated to the first nanoparticles, and the “solute containing the first outer edge ligands” may contain the first nanoparticles coordinated with the first outer edge ligands.

As commonly known, the solubility of ligands alone in a solvent is not completely equal to the solubility of a solute containing quantum dots coordinated with ligands, and the solubility range of either the ligands alone or the solute is narrow. Specifically, for example, oleic acid alone can dissolve in methanol as a highly polar solvent or toluene as a nonpolar solvent. On the other hand, when oleic acid is coordinated to the quantum dots, a polar site of —COOH contained in a skeleton of oleic acid is neutralized by the coordination to the quantum dots, and the polarity of the quantum dots coordinated with oleic acid decreases. Hence, the quantum dots coordinated with oleic acid dissolves not in the highly polar methanol, but only in the nonpolar solvent such as toluene. As can be seen, the first etchant may contain a solvent capable of dissolving the first nanoparticles coordinated with the first outer edge ligands.

Note that described above is an example in which the first etchant additionally contains water and the red first outer edge ligands 28R that dissolve in the water. However, the first etchant shall not be limited to such an example. Examples of the first etchant may contain, as a polar solvent, at least one selected from the group consisting of methanol (MeOH), N, N-dimethylformamide (DMF), acetonitrile, ethylene glycol, and dimethyl sulfoxide (DMSO).

Furthermore, the first etchant may contain the red first outer edge ligands 28R that dissolve in the polar solvent. For example, the first etchant may contain, as the red first outer edge ligands 28R, a halogen including S, Cl, Br, or I. Alternatively, the first etchant may contain either inorganic ligands containing S2- or polarity dispersing ligands. In addition, the first etchant may contain, as the red first outer edge ligands 28R, TMAH or 2-dimethylaminoethanethiol hydrochloride described above.

When the first etchant containing the red first outer edge ligands 28R is in contact with the outer edge of the red light-emitting layer 10R, the ligands coordinated to the red quantum dots 18R are brought into an equilibrium state between the red main ligands 20R and the red first outer edge ligands 28R at the contact portion. Here, suppose the concentration of the red first outer edge ligands 28R contained in the first etchant is higher than the concentration of the red main ligands 20R contained in the red light-emitting layer 10R. In this case, in the outer edge of the red light-emitting layer 10R, it is highly probable that most of the ligands coordinated to the red quantum dots 18R are substituted with the red first outer edge ligands 28R. Specifically, the first etchant may contain 0.013 mol/L or more of the red first outer edge ligands 28R.

Alteration of the outer edge of the red light-emitting layer 10R is equivalent to ligand exchange coordinated to the red quantum dots 18R in the outer edge of the red light-emitting layer 10R. Hence, formed on the outer edge of the red light-emitting layer 10R is the red first outer edge region 16R in which the red main ligands 20R coordinated to the red quantum dots 18R are substituted with the red first outer edge ligands 28R. Thus, in the above-described case, the quantum dots contained in the red first outer edge region 16R may be the same in configuration as the red quantum dots 18R except for the coordinated ligands.

Relationship between Development of Resist Layer and Etching of Main Light-Emitting Material Layer

The first developing step and the first etching step may be carried out either simultaneously, or continuously in the stated order, with the first etchant. Note that, in DESCRIPTION, the statement “two steps are continuously carried out” means that when a preceding one of the two steps starts first, the preceding step is completed and the other succeeding step starts with no specific operation carried out. In other words, in DESCRIPTION, the statement “two steps are continuously carried out” means that the operation to carry out the two steps is a single operation, and the two steps are continuously carried out in the operation.

For example, if the first resist layer 38 dissolves in PGMEA, and in alkali when irradiated with an ultraviolet ray, the first etchant may be an alkaline liquid containing, for example: a resist dissolving component; the red first outer edge ligands 28R; and water as a solvent. Hence, the first etchant may also be used as a developing solution for the first resist layer 38. The red first outer edge ligands 28R are, for example, TMAH, and the resist dissolving component of the first etchant is, for example, a TMAH developing solution (of 2.38 wt %).

In this case, the first resist layer 38, which is irradiated with an ultraviolet ray and becomes dissolvable in alkali, is developed with the first etchant. Furthermore, the red main ligands 20R, contained in the red light-emitting layer 10R exposed from the first resist layer 38, are substituted with the red first outer edge ligands 28R. The red light-emitting layer 10R becomes soluble in water when the red main ligands 20R are substituted with the red first outer edge ligands 28R. Thus, the red light-emitting layer 10R in which the ligands are substituted with the red first outer edge ligands 28R is removed with the first etchant.

Moreover, the first etchant contains the red first outer edge ligands 28R. Hence, when the end surface of the red light-emitting layer 10R comes into contact with the first etchant, in the outer edge of the red light-emitting layer 10R, the red main ligands 20R coordinated to the red quantum dots 18R are substituted with the red first outer edge ligands 28R different from the red main ligands 20R. As a result, on the outer edge of the red light-emitting layer 10R, the red first outer edge region 16R is formed. That is, the first resist layer 38 may be developed, the red light-emitting layer 10R may be etched, and the red first outer edge region 16R may be formed either simultaneously, or continuously in the stated order, using the first etchant.

The first etchant may be an aqueous solution separately contain a solute exhibiting alkalinity. An example of the first etchant having alkalinity may be an aqueous solution containing KOH. Furthermore, the first etchant may contain the red first outer edge ligands 28R exhibiting alkalinity when dispersed in a solvent. For example, if the first etchant contains the above TMAH serving as the red first outer edge ligands 28R, the first etchant exhibits alkalinity. As can be seen, if the first etchant contains the red first outer edge ligands 28R exhibiting alkalinity when dispersed in a solvent, the first etchant does not have to additionally and separately contain a solute to provide the first etchant with alkalinity. Such a feature reduces material costs.

Note that the first etchant may contain: a nonpolar organic solvent; and the red first outer edge ligands 28R soluble in the nonpolar organic solvent. The red first outer edge ligands 28R soluble in the nonpolar organic solvent may be, for example, the hydrophobic ligands described above. The nonpolar organic solvent may contain at least one selected from the group consisting of, for example, hexane, heptane, octane, nonane, decane, undecane, toluene, and dodecane.

In this case, at Step S16, the red quantum dots 18R coordinated with the red first outer edge ligands 28R are soluble in the nonpolar organic solvent contained in the first etchant. Thus, only the red light-emitting layer 10R in which the ligands of the red quantum dots 18R are substituted is removed with the first etchant containing the nonpolar organic solvent.

### Patterning Green Main Light-Emitting Material Layer by Delamination of First Resist Layer

Following the step of etching the red light-emitting layer 10R, the green light-emitting layer 10G is deposited (Step S18). Step S18 is a second functional layer depositing step of depositing a second functional layer (the green light-emitting layer 10G) containing second nanoparticles (the green quantum dots) coordinated with second main ligands (green main ligands) and different from the first nanoparticles (the red quantum dots). In particular, the green light-emitting layer 10G contains: quantum dots that emit a green light; and ligands serving as main ligands and coordinated to the quantum dots. Here, the green light-emitting layer 10G is formed on the first resist layer 38 in a position overlapping with the left first resist layer 38. Note that the green light-emitting layer 10G may be deposited by the same technique employed for depositing the red light-emitting layer 10R, except for the materials to be contained in the deposited layers.

### Second Etching Step

Next, on the green light-emitting layer 10G, a second resist layer 40 is deposited (Step S20). Step S20 is a second resist depositing step. The second resist layer 40 according to this embodiment may be the same in configuration as the first resist layer 38. Furthermore, the second resist layer 40 may be deposited by the same technique employed at Step S10.

Next, the second resist layer 40 is exposed to light (Step S22). Step S22 is a second light exposure step of exposing the second resist layer 40 with light. At Step S22, the second light exposure step is carried out as, for example, a preliminary step of removing a portion of the second resist layer 40. The second light exposure step may involve exposing the second resist layer 40 with light by the same technique employed at the first light exposure step.

Next, the second resist layer 40 is developed (Step S24). Step S24 is a second developing step of developing the second resist layer 40. Step S24 involves, for example, rinsing the second resist layer 40 with a specific developing solution to remove a portion of the second resist layer 40.

In this embodiment, Step S24 involves removing only the portion, of the second resist layer 40, formed in a position overlapping with the blue subpixel SPB. Hence, when Step S24 is completed, the green light-emitting layer 10G is exposed in the position overlapping with the blue subpixel SPB.

Next, a second etching step (Step S26) is carried out to etch a portion of the green light-emitting layer 10G (the second functional layer). The second etching step involves rinsing the green light-emitting layer 10G exposed from the second resist layer 40 with, for example, a second etchant. Note that, the second etchant may be the same in composition as the first etchant described above.

The second etching step involves etching the green light-emitting layer 10G in a position overlapping with the blue subpixel SPB. Hence, Step S26 involves removing the green light-emitting layer 10G formed in the position overlapping with the blue subpixel SPB.

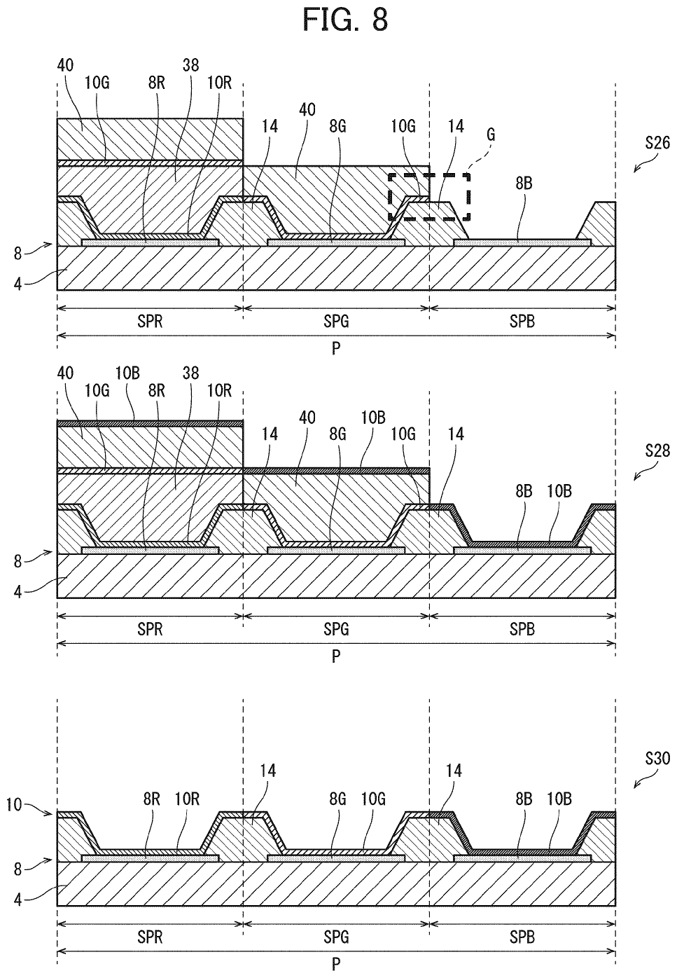

A region G in FIG. 9 is an exemplary enlarged view of a region G at Step S26 in FIG. 8. At Step S26, even in a position overlapping with the second resist layer 40, the outer edge included in the green light-emitting layer 10G and exposed from the second resist layer 40 touches the second etchant. Thus, the ligands, which are coordinated to the quantum dots included in the vicinity of an end portion of the outer edge, are substituted with the outer edge ligands different from the main ligands that are coordinated to the quantum dots contained in the green light-emitting layer 10G.

The altered green light-emitting layer 10G, which overlaps with the second resist layer 40, is not removed at Step S26. Hence, at Step S26, the outer edge of the green light-emitting layer 10G is altered and left on the upper surface 14S of the bank 14. This is how the green first outer edge region 16G is formed. In other words, the second etching step includes simultaneously forming a second outer edge region, which has second outer edge ligands different from the second main ligands, on a side surface that is at least a portion of the second functional layer.

Hence, when Step S26 is completed, the green light-emitting layer 10G is completely formed in a position overlapping with the green subpixel SPG, in order to include the green first main region 15G and the green first outer edge region 16G. In addition, when Step S26 is completed, the green light-emitting layer 10G provided in a position overlapping with the blue subpixel SPB is removed.

Note that the green first outer edge region 16G may be formed by the same technique employed for forming the red first outer edge region 16R described above. In other words, the patterning of the second resist layer 40, the etching of the green light-emitting layer 10G, and the forming of the green first outer edge region 16G at Steps S24 and S26 may be carried out simultaneously. Furthermore, in forming the green first outer edge region 16G, the outer edge included in the green light-emitting layer 10G and exposed from the second resist layer 40 may be partially removed with the second etchant.

### Patterning Blue Light-Emitting Layer by Delamination of Second Resist Layer

Next, the blue light-emitting layer 10B is deposited as a third functional layer (Step S28). The blue light-emitting layer 10B contains third nanoparticles coordinated with third main ligands and different from both the first nanoparticles (the red quantum dots) and the second nanoparticles (the green quantum dots). Step S28 is a third functional layer depositing step. In particular, the blue light-emitting layer 10B contains: blue quantum dots that serve as the third nanoparticles and emit a blue light; and blue main ligands that serve as third main ligands and are coordinated to the blue quantum dots. Here, the blue light-emitting layer 10B is formed on the second resist layer 40 in a position overlapping with the left second resist layer 40. Note that the blue light-emitting layer 10B may be deposited by the same technique employed for depositing either the red light-emitting layer 10R or the green light-emitting layer 10G, except for the materials to be contained in the deposited layers.

Next, the first resist layer 38 and the second resist layer 40 that are left are delaminated (Step S30). Step S30 is a delamination step. If the first resist layer 38 and the second resist layer 40 are soluble in an organic solvent containing PEGMA, Step S30 may involve rinsing the first resist layer 38 and the second resist layer 40 with, for example, the organic solvent. Hence, the blue light-emitting layer 10B formed on the first resist layer 38 and the second resist layer 40 is also removed simultaneously when the first resist layer 38 and the second resist layer 40 are delaminated. Thus, at Step S30, the blue light-emitting layer 10B is left only in a position overlapping with the blue subpixel SPB.

Hence, when Step S30 is completed, the blue light-emitting layer 10B is completely formed in the position overlapping with the blue subpixel SPB, and the light-emitting layer 10 is completely formed. Note that the step of forming the blue light-emitting layer 10B does not include a step of etching a layer adjacent to the blue light-emitting layer 10B. Thus, the blue subpixel SPB does not have an outer edge region. In the production method described above, a light-emitting region formed last does not include an outer edge region. Hence, if the display device 2 includes the n kinds of light-emitting regions that emit light in different colors, only the (n−1) kinds of light-emitting regions may each include a main region and a first outer edge region.

Next, above the light-emitting layer 10, the common electrode 12 is deposited in common to the plurality of subpixels. Hence, the light-emitting element layer 6 is completely formed. The common electrode 12 may be deposited by the same technique employed for the deposition of a conductive material at the step of forming the pixel electrode 8. Note that, in the method of producing the display device 2 according to this embodiment, the light-emitting element layer 6 is formed. After that, a sealing layer may be formed above the light-emitting element layer 6. This is how the display device 2 according to this embodiment is produced.

### Examples of Subpixel Formation Patterns

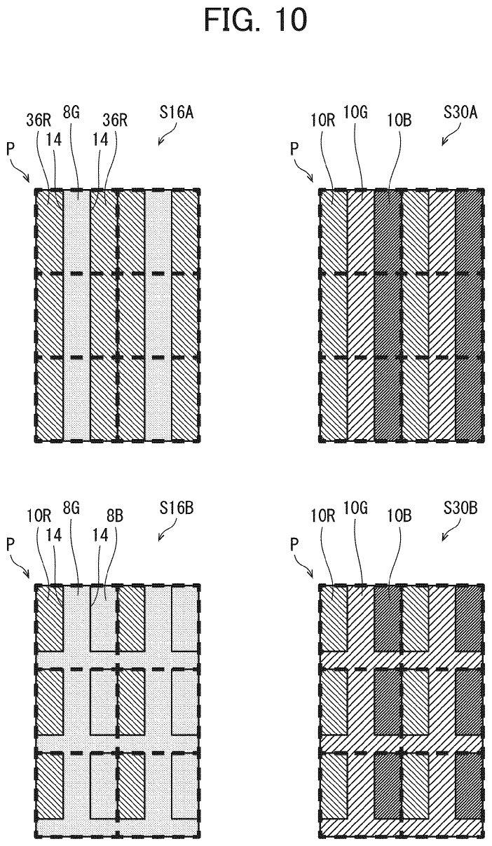

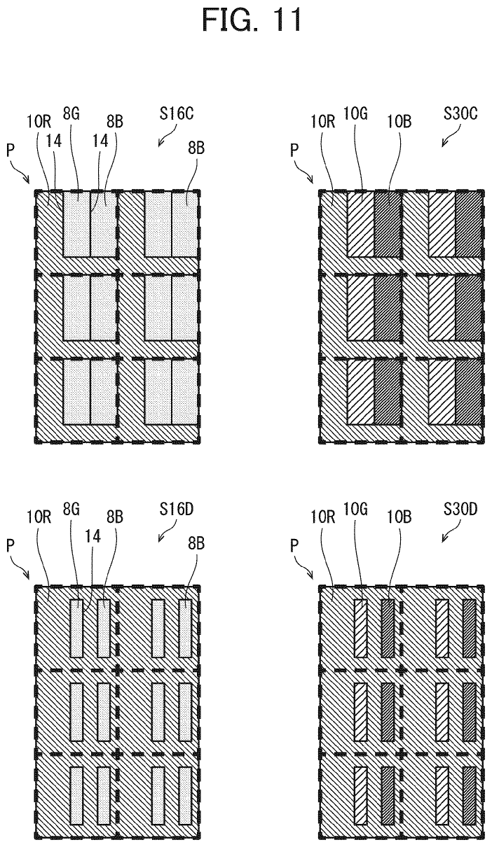

Described below will be formation patterns of the subpixels included in the display device 2 according to this embodiment, with reference to FIGS. 10 and 11. FIGS. 10 to 11 illustrate plan views of steps included in the steps of the method of producing the display device 2 according to this embodiment.

When observed from the viewer, each of the plan views of the steps for DESCRIPTION excerpts two pixels horizontally and three pixels vertically; that is, six pixels in total. Note that, in the plan views of the steps for DESCRIPTION, boundaries between the pixels P are represented by dotted lines. Furthermore, in the plan views of the steps for DESCRIPTION, an illustration of an outer edge region is omitted for the sake of simplicity. In addition, in the plan views of the steps for DESCRIPTION, an illustration of a resist layer is omitted for the sake of simplicity. Hence, the resist layer is given as a transparent layer.

In this embodiment, each of the red light-emitting layer 10R, the green light-emitting layer 10G, and the blue light-emitting layer 10B may be formed in common to a plurality of pixels. In this case, Step S16 and Step S30 in the production method according to this embodiment are carried out to obtain, for example, respective structures illustrated at Step S16A and Step S30A in FIG. 10.

Furthermore, in this embodiment, any one of the red light-emitting layer 10R, the green light-emitting layer 10G, and the blue light-emitting layer 10B may be formed in common to all of the pixels. In this case, Step S16 and Step S30 in the production method according to this embodiment are carried out to obtain, for example, respective structures illustrated at Step S16B and Step S30B in FIG. 10. Thus, as illustrated at Step S30B in FIG. 10, the display device 2 is successfully produced to have the green light-emitting layer 10G formed in common to all the pixels.

Alternatively, Step S16 and Step S30 in the production method according to this embodiment are carried out to obtain, for example, respective structures illustrated at Step S16C and Step S30C in FIG. 11. Thus, as illustrated at Step S30C of FIG. 11, the display device 2 is successfully produced to have the red light-emitting layer 10R formed in common to all the pixels.

Moreover, in this embodiment, one kind of light-emitting region may be provided in common to all the pixels, and the rest of two kinds of light-emitting regions may be shaped into islands. In this case, Step S16 and Step S30 in the production method according to this embodiment are carried out to obtain, for example, respective structures illustrated at Step S16D and Step S30D in FIG. 11. Thus, as illustrated at Step S30D in FIG. 11, the display device 2 is successfully produced to have the green light-emitting layers 10G and the blue light-emitting layers 10B shaped into islands and formed in positions surrounded with the red light-emitting layer 10R in common to all the pixels.

Note that if the display device 2 has a structure illustrated at Step S30D in FIG. 11, at Step S16, only an end portion of the red light-emitting layer 10R is exposed from the first resist layer 38. Hence, if the display device 2 has the structure illustrated at Step S30D in FIG. 11, at Step S16, the red first outer edge region 16R is formed only in the end portion of the red light-emitting layer 10R. Thus, in the display device 2 having the structure illustrated at Step S30D in FIG. 11, the green light-emitting layer 10G is provided only with the green first main region 15G, not with the green first outer edge region 16G.

### Advantageous Effects of Production Method

The method of producing the display device 2 according to this embodiment includes a step of substituting the red main ligands 20R, coordinated to the red quantum dots 18R contained in the red light-emitting layer 10R, with the red first outer edge ligands 28R when the red light- emitting layer 10R is etched. Such a step makes it possible to simultaneously carry out the step of etching the red light-emitting layer 10R and the formation of the red first outer edge region 16R on the outer edge of the red light-emitting layer 10R.

Hence, the method of producing the display device 2 according to this embodiment eliminates the need for separately forming the red first outer edge region 16R after the red light- emitting layer 10R is etched. Thus, the method of producing the display device 2 achieves reduction in takt time of the production steps and simplification of the production steps.

Furthermore, the method simultaneously carries out the step of etching the red light-emitting layer 10R and the formation of the red first outer edge region 16R on the outer edge of the red light-emitting layer 10R, thereby protecting the main region from water permeating from the outer edge region because of, for example, rinsing with the water at the production steps. Such a feature prevents a function of the main region from deteriorating because of water permeating into the main region.

Moreover, since the resist layer is subjected to photolithography fewer times in the above-described production method, each of the light-emitting regions can be positioned more precisely. In addition, the positional displacement of the first outer edge region in each of the light-emitting regions does not greatly affect performance of the display device 2, compared with the positional displacement of the main light-emitting region. Hence, in the above-described production method, each light-emitting region has a wider allowable range in positional displacement. Thus, the production method is advantageous in further simplifying production of the display device 2 with high definition.

In addition, the method of producing the display device 2 according to this embodiment can carry out development of each resist layer, etching of the red light-emitting layer 10R, and formation of the red first outer edge region 16R in a single step. Such a step can be carried out, using appropriately prepared developing solution for the step of developing the resist layer and etchant for the red light-emitting layer 10R. Thanks to the step, the method of producing the display device 2 according to this embodiment can reduce the number of required steps and material costs.

Note that, as to the method of producing the display device 2 according to this embodiment, only the main light-emitting material may be separated from a waste liquid at the step of etching the light-emitting layer or the step of delaminating the resist layer, and the separated main light-emitting material may be reused. The separation of the main light-emitting material from the waste liquid may be carried out by, for example, centrifugal separation of the waste liquid.

Furthermore, if the main light-emitting material contains the main quantum dots coordinated with the main ligands, the ligands, which are coordinated to the main quantum dots contained in the waste liquid obtained at the etching step, might be substituted with the first outer edge ligands. In this case, in this embodiment, a solution containing the main quantum dots and the first outer edge ligands extracted from the waste liquid is stirred together with a solution in which the main ligands are dispersed, such that the ligands coordinated to the main quantum dots may be substituted again with the main ligands.

Specifically, following each of the etching steps, a recovery step may be carried out to recover the quantum dots and the outer edge ligands coordinated to the quantum dots from the etchant used at the etching step. Furthermore, following the recovery step, a ligand exchange step may further be carried out to substitute the outer edge ligands coordinated to the recovered quantum dots with the main ligands.

The light-emitting element layer 6 may include, as a functional layer, a hole injection layer or a hole transport layer between the pixel electrode 8 and the light-emitting layer 10. The hole injection layer and the hole transport layer have: quantum dots coordinated with main ligands; and quantum dots coordinated with outer edge ligands different from the main ligands. In this case, the quantum dots are capable of transporting holes.

In the above configuration, the hole injection layer or the hole transport layer has: a main region containing the quantum dots coordinated with the main ligands; and an outer edge region positioned in the vicinity of a side surface that is at least a portion of the main region, and containing the quantum dots coordinated with the outer edge ligands. Here, the main region is higher in hole transport efficiency than the outer edge region.

The light-emitting element layer 6 may include, as a functional layer, an electron injection layer or an electron transport layer between the light-emitting layer 10 and the common electrode 12. The electron injection layer and the electron transport layer have: quantum dots coordinated with main ligands; and quantum dots coordinated with outer edge ligands different from the main ligands. In this case, the quantum dots are capable of transporting electrons.

In the above configuration, the electron injection layer or the electron transport layer has: a main region containing the quantum dots coordinated with the main ligands; and an outer edge region positioned in the vicinity of a side surface that is at least a portion of the main region, and containing the quantum dots coordinated with the outer edge ligands. Here, the main region is higher in electron transport efficiency than the outer edge region.

The above-described hole injection layer, hole transport layer, electron injection layer, or electron transport layer can be produced by the same technique employed for producing the light-emitting layer 10 according to this embodiment, except for kinds of the quantum dots and the ligands contained in the light-emitting layer.

### Second Embodiment

### Third Resist Layer

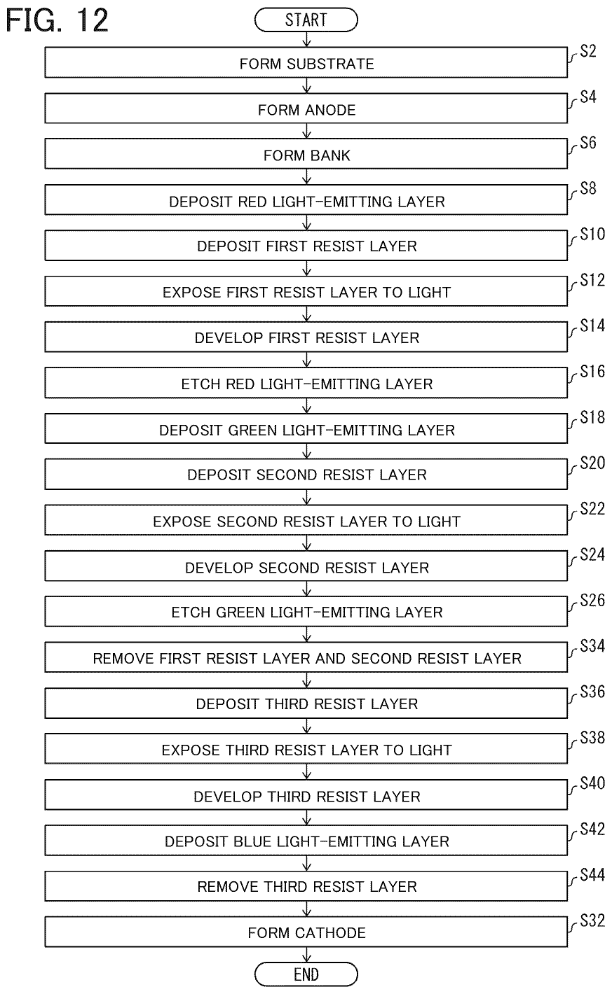

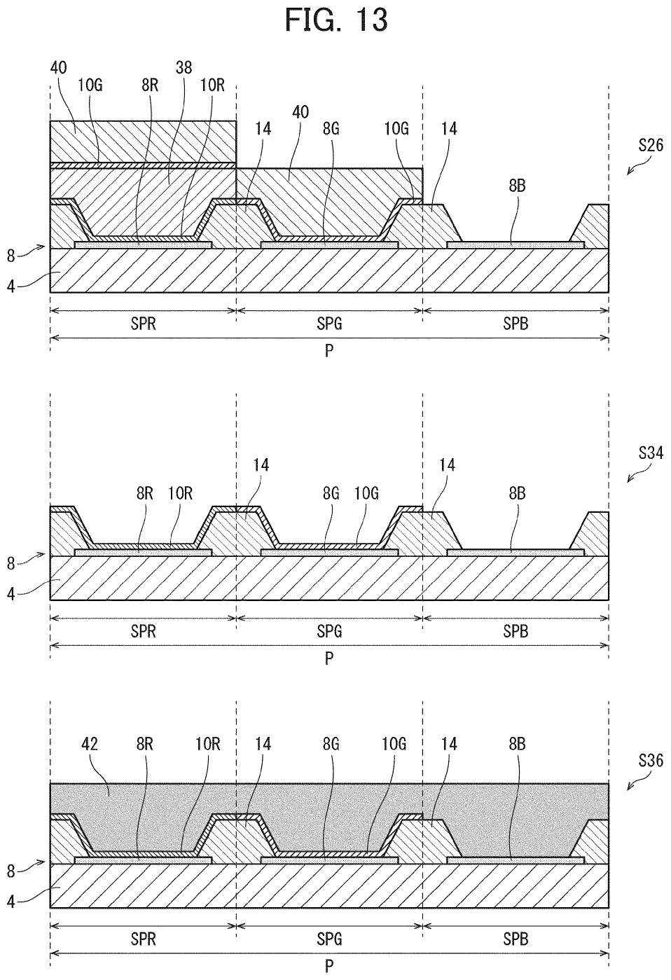

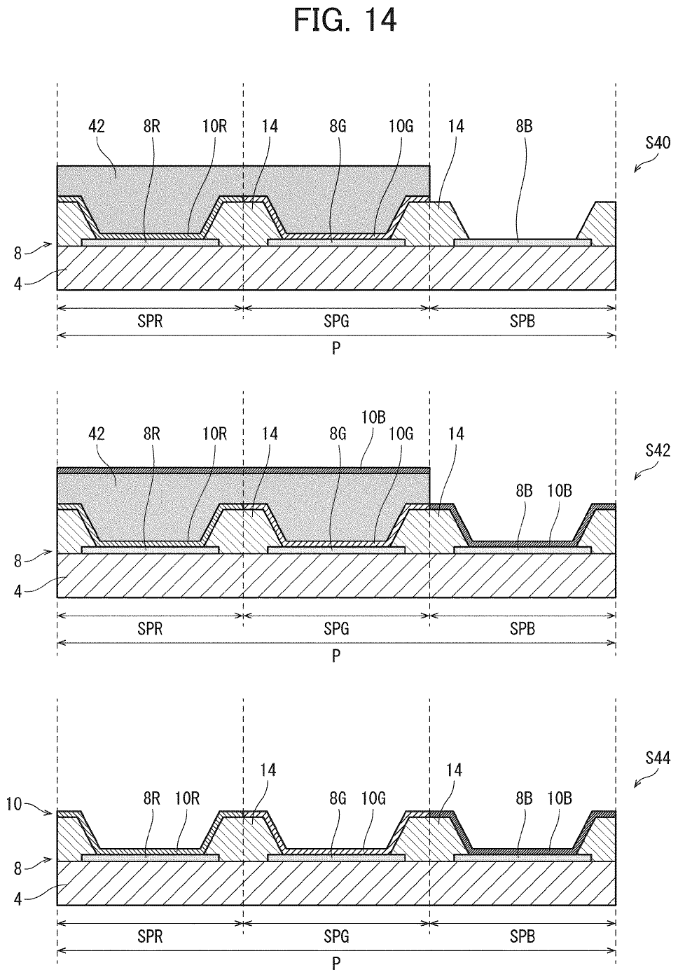

The display device 2 according to this embodiment is the same in configuration as the display device 2 according to the first embodiment except for a difference in production method. Described below will be a method of producing the display device 2 according to this embodiment, with reference to FIGS. 12 to 14. FIG. 12 is a flowchart showing the method of producing the display device 2 according to this embodiment. FIGS. 13 and 14 illustrate cross-sectional views of steps included in the steps of producing the display device 2 according to this embodiment.

The method of producing the display device 2 according to this embodiment is carried out by the same technique employed for the method of producing the display device 2 according to the first embodiment up to Step S26 described above. Hence, in this embodiment, the structure illustrated at Step S26 in FIG. 13 is obtained when Step S26 is completed.

In this embodiment, following Step S26, the first resist layer 38 and the second resist layer 40 are delaminated by the same technique employed at Step S30 according to the first embodiment (Step S34). Step S34 is a first delamination step. Step S34 according to this embodiment completes formation of the green light-emitting region LAG.

Next, a third resist layer 42 is deposited above the pixel electrode 8B, the bank 14, the red light-emitting layer 10R, and the green light-emitting layer 10G (Step S36). Step S36 is a third resist depositing step. The third resist layer 42 according to this embodiment may be the same in configuration as the first resist layer 38 or the second resist layer 40. Furthermore, the third resist layer 42 may be deposited by the same technique employed at Step S10 in the first embodiment.

Next, the third resist layer 42 is exposed to light (Step S38). At Step S38, a third light exposure step is carried out as, for example, a preliminary step of removing a portion of the third resist layer 42. The third light exposure step may involve exposing the third resist layer 42 with light by the same technique employed at the first light exposure step or the second light exposure step according to each of the embodiments described above.

Next, the third resist layer 42 is developed (Step S40). Step S40 is a third developing step of developing the third resist layer 42. Step S40 involves, for example, rinsing the third resist layer 42 with a specific developing solution to remove a portion of the third resist layer 42.

In this embodiment, Step S40 involves removing only the portion, of the third resist layer 42, formed in a position overlapping with the blue subpixel SPB. Hence, when Step S40 is completed, the pixel electrode 8B and the bank 14 are exposed in the position overlapping with the blue subpixel SPB.

Next, the blue light-emitting layer 10B is deposited by the same technique employed at Step S28 according to the first embodiment (Step S42). Step S42 according to this embodiment involves forming the blue light-emitting layer 10B above the third resist layer 42 in a position overlapping with each of the red subpixel SPR and the green subpixel SPG.

Next, the left third resist layer 42 is delaminated (Step S44). Step S44 is a second delamination step. Thus, the blue light-emitting layer 10B formed on the third resist layer 42 is also removed simultaneously when the third resist layer 42 is delaminated. Thus, at Step S44, the blue light-emitting layer 10B is left only in a position overlapping with the blue subpixel SPB.

Steps S42 and S44 according to this embodiment can be carried out by the same techniques employed at respective Steps S28 and S30 according to the first embodiment. Next, the common electrode 12 is deposited by the same technique employed at Step S32 in the first embodiment. Hence, the display device 2 according to this embodiment is obtained.

Also in this embodiment, the red light-emitting region LAR can be formed at a step of etching, using a resist layer to be used for patterning other light-emitting regions. Thanks to the step, the method of producing the display device 2 according to this embodiment can be implemented with fewer steps required.

Furthermore, at Step S34 of the method of producing the display device 2 according to this embodiment, the green light-emitting layer 10G has been formed above the first resist layer 38 delaminated at Step S26 preceding Step S34. However, at Step S34, the first resist layer 38 and the second resist layer 40 are delaminated while the blue light-emitting layer 10B is not formed above the second resist layer 40. Thus, as to the method of producing the display device 2 according to this embodiment, the layers removed at Step S34 are thinned for the thickness of the blue light-emitting layer 10B compared with the method of producing the display device 2 according to the first embodiment. Hence, as to the method of producing the display device 2 according to this embodiment, the first resist layer 38 and the second resist layer 40 can be delaminated more easily at Step S34.

### Third Embodiment

### Another Technique for Patterning Green Light-Emitting Layer

The display device 2 according to this embodiment is different from the display devices 2 according to the previous embodiments only in that the green light-emitting region LAG includes the green light-emitting layer 10G alone. In other words, in the display device 2 according to this embodiment, the green light-emitting region LAG does not include the green first outer edge region 16G.

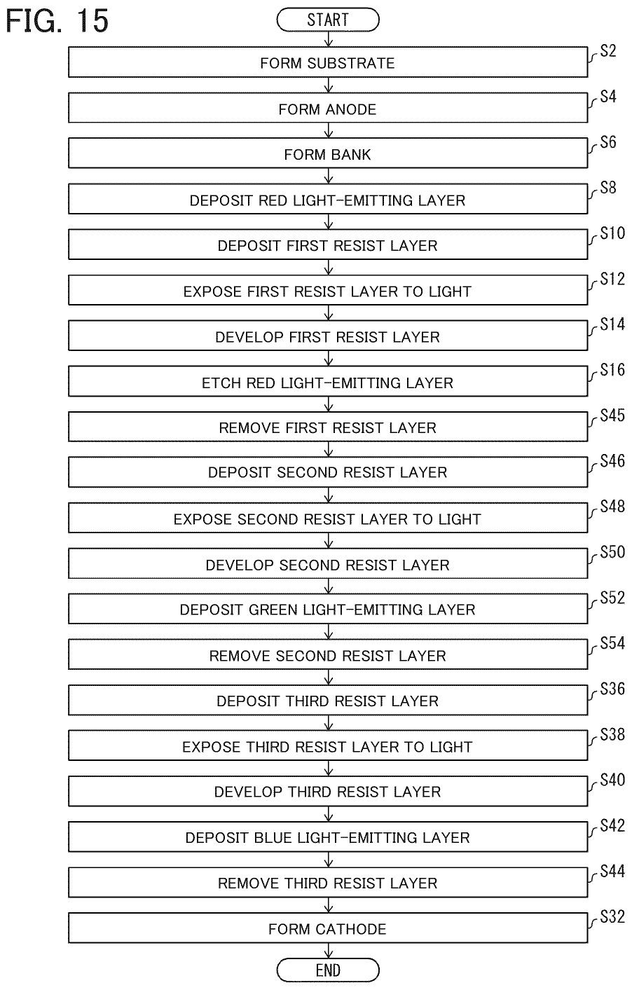

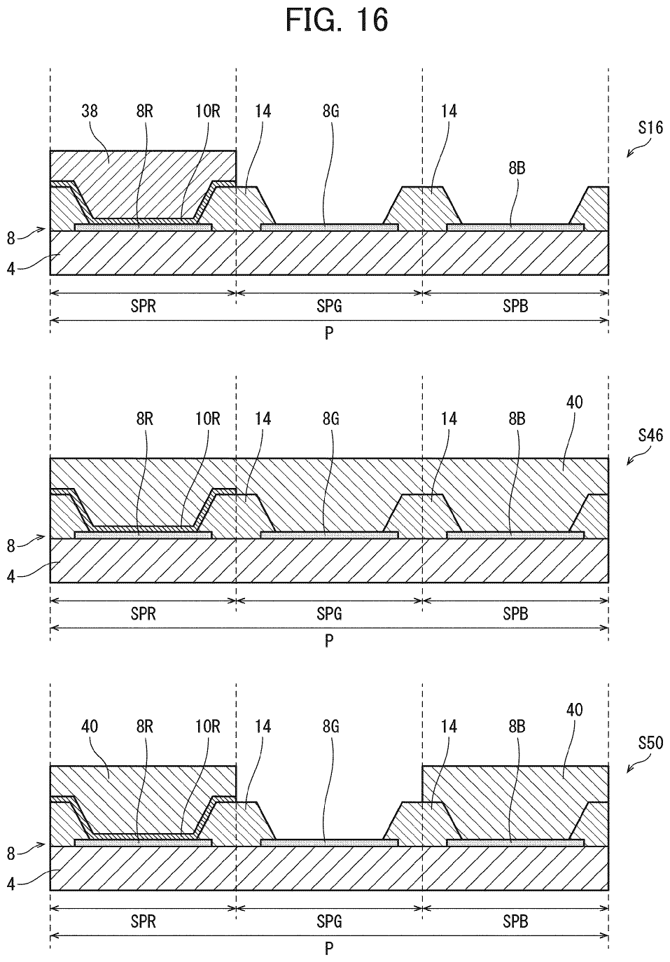

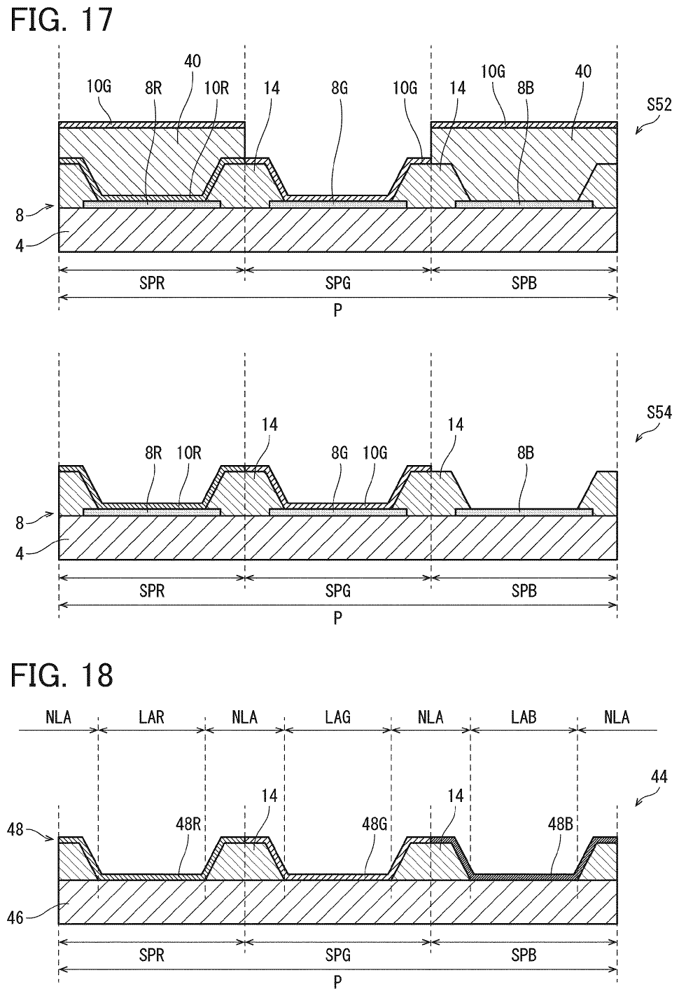

Described below will be a method of producing the display device 2 according to this embodiment, with reference to FIGS. 15 to 17. FIG. 15 is a flowchart showing the method of producing the display device 2 according to this embodiment. FIGS. 16 and 17 illustrate cross-sectional views of steps included in the steps of producing the display device 2 according to this embodiment.

The method of producing the display device 2 according to this embodiment is carried out by the same technique employed for the method of producing the display device 2 according to the second embodiment up to Step S16 described above. Hence, in this embodiment, the structure illustrated at Step S16 in FIG. 16 is obtained when Step S16 is completed.

In this embodiment, following Step S16, the first resist layer 38 is delaminated by the same technique employed at Step S34 according to the second embodiment (Step S45). Next, the second resist layer 40 is deposited by the same technique employed at Step S20 according to each of the embodiments described above (Step S46).

Then, the second resist layer 40 is exposed to light by the same technique employed at Step S22 according to each of the embodiments described above (Step S48). Step S48 is a light exposure step of exposing the second resist layer 40 with light. At Step S48, a second light exposure step is carried out as, for example, a preliminary step of removing a portion of the second resist layer 40. The second light exposure step may be carried out by, for example, the same technique employed at the first light exposure step.

Next, the second resist layer 40 is developed (Step S50) Step S50 is a second developing step of developing the second resist layer 40. Step S50 involves, for example, rinsing the second resist layer 40 with a specific developing solution to remove a portion of the second resist layer 40.

In this embodiment, Step S50 involves removing only the portion, of the second resist layer 40, formed in a position overlapping with the green subpixel SPG. Hence, when Step S50 according to this embodiment is completed, the pixel electrode 8G and the bank 14 alone, provided in a position overlapping with the green subpixel SPG, are exposed from the second resist layer 40.

Next, the green light-emitting layer 10G is deposited by the same technique employed at Step S26 according to each of the embodiments described above (Step S52). Step S52 according to this embodiment involves forming the green light-emitting layer 10G above the pixel electrode 8B and the bank 14 in a position overlapping with the green subpixel SPG. Furthermore, Step S52 according to this embodiment involves forming the green light-emitting layer 10G above the second resist layer 40 left in positions overlapping with the red subpixel SPR and the blue subpixel SPB.

Next, the second resist layer 40 is delaminated by the same technique employed at Step S34 according to the second embodiment (Step S54). Step S54 involves delaminating the second resist layer 40, and simultaneously removing the green light-emitting layer 10G formed above the second resist layer 40. Thus, the green light-emitting layer 10G is left in a position overlapping with the green subpixel SPG.

Hence, when Step S54 is completed, the green light-emitting region LAG is completely formed to include the green light-emitting layer 10G. Note that, in this embodiment, the green light-emitting region LAG is formed without etching a layer adjacent to the green light-emitting layer 10G. Accordingly, in the green light-emitting region LAG, the green first outer edge region 16G is not formed.

As FIG. 17 shows at Step S54, the structure obtained when Step S54 is completed is the same as the structure obtained when Step S34 according to the second embodiment is completed. Hence, after Step S54, the steps succeeding Step S36 according to the second embodiment are sequentially carried out, and the display device 2 according to this embodiment is obtained.

Also in this embodiment, the red light-emitting region LAR can be formed at a step of etching, using a resist layer to be used for patterning other light-emitting regions. Thanks to the step, the method of producing the display device 2 according to this embodiment can be implemented with fewer steps required.

Furthermore, at Step S54 of the method of producing the display device 2 according to this embodiment, the green light-emitting layer 10G is formed above the delaminated second resist layer 40, but the first resist layer 38 is not. Thus, as to the method of producing the display device 2 according to this embodiment, the layer to be removed at Step S54 is formed thin for the thickness of one first resist layer 38, compared with the method of producing the display device 2 according to the second embodiment. Hence, as to the method of producing the display device 2 according to this embodiment, the second resist layer 40 can be delaminated more easily at Step S54.

Moreover, in the method of producing the display device 2 according to this embodiment, the step of etching a light-emitting layer includes only the step of etching the red light-emitting layer 10R. In other words, as to the method of producing the display device 2 according to this embodiment, a main light-emitting material layer is etched only once. Thus, the production method described above is carried out with fewer etching steps and in a shorter takt time. In addition, the production method described above is completed with only one kind of etchant used at the etching steps, thereby making it possible to reduce production costs.

Similar to the method of producing the display device 2 according to the second embodiment, in the method of producing the display device 2 according to this embodiment, the green light-emitting layer 10G is not formed in a position overlapping with the blue subpixel SPB. Hence, the production method can have only one kind of main light-emitting material formed in a position in which the main light-emitting material is not supposed to be formed, thereby reducing a chance of color mixture.

### Fourth Embodiment

### Display Device Including Wavelength Converting Layer

FIG. 18 is a schematic cross-sectional view of a display device 44 according to this embodiment. Similar to the display device 2 illustrated in FIG. 2, the display device 44 according to this embodiment includes, in plan view: the display region DA that releases light emitted from each of the subpixels to display an image; and the picture-frame region NA surrounding the display region DA. FIG. 18 illustrates a portion of a cross-section, of the display device 44, in a position overlapping with the display region DA in plan view, as seen in the cross-sectional view of the display device 2 illustrated in FIG. 1.

As illustrated in FIG. 18, the display device 44 according to this embodiment includes: a light source unit 46; the bank 14 provided on the light source unit 46; and a wavelength converting layer 48 serving as a functional layer and provided on the light source unit 46 and the bank 14. Note that, in DESCRIPTION, the direction from the bank 14 toward the light source unit 46 is referred to as a “downward direction”, and the direction from the bank 14 toward the wavelength converting layer 48 is referred to as an “upward direction”.

The light source unit 46 emits light to the wavelength converting layer 48. The wavelength converting layer 48 absorbs light from the light source unit 46, and emits light different in wavelength from the light emitted from the light source unit 46. The wavelength converting layer 48 according to this embodiment includes a plurality of light-emitting regions. The plurality of light-emitting regions include: the red light-emitting region LAR; the green light-emitting region LAG; and the blue light-emitting region LAB. In particular, each of the light-emitting regions in the wavelength converting layer 48 emits light a wavelength of which is longer than a wavelength of the light absorbed into the light-emitting region.

In this embodiment, the display device 44 includes a plurality of subpixels. The wavelength converting layer 48 includes one light-emitting region for each of the subpixels. In this embodiment, for example, the wavelength converting layer 48 includes, as the light-emitting regions: the red light-emitting region LAR in the red subpixel SPR, the green light-emitting region LAG in the green subpixel SPG, and the blue light-emitting region LAB in the blue subpixel SPB.

In this embodiment, the red light-emitting region LAR includes a red wavelength converting layer 48R that emits a red light, the green light-emitting region LAG includes a green wavelength converting layer 48G that emits a green light, and the blue light-emitting region LAB includes a blue wavelength converting layer 48B that emits a blue light. In other words, the wavelength converting layer 48 includes, as multiple kinds of light-emitting regions emitting light in different colors, the red light-emitting region LAR that emits a red light, the green light-emitting region LAG that emits a green light, and the blue light-emitting region LAB that emits a blue light.

The red light-emitting region LAR of the wavelength converting layer 48 according to this embodiment is the same in configuration as the red light-emitting region LAR of the light-emitting layer 10 according to any of the above-described embodiments except that the former red light-emitting region LAR includes the red wavelength converting layer 48R instead of the red light-emitting layer 10R. For example, the red light-emitting region LAR of the wavelength converting layer 48 according to this embodiment includes: the red wavelength converting layer 48R; and the red first outer edge region 16R positioned on a side surface that is at least a portion of the red wavelength converting layer 48R.

Furthermore, the red wavelength converting layer 48R is formed of the same main light-emitting materials as those of the red light-emitting layer 10R according to any of the above-described embodiments. For example, the red wavelength converting layer 48R includes, as main light-emitting materials, the red quantum dots 18R and the red main ligands 20R coordinated to the red quantum dots 18R. The red quantum dots 18R and the red main ligands 20R are illustrated in FIG. 1.

Furthermore, the red first outer edge region 16R according to this embodiment is the same in configuration as the red first outer edge region 16R according to any of the above-described embodiments. For example, the red first outer edge region 16R according to this embodiment includes: the red quantum dots 18R; and the red first outer edge ligands 28R coordinated to the red quantum dots 18R. The red quantum dots 18R and the red first outer edge ligands 28R are illustrated in FIG. 1.

The green light-emitting region LAG of the wavelength converting layer 48 according to this embodiment is the same in configuration as the green light-emitting region LAG of the light-emitting layer 10 according to any of the above-described embodiments except that the former green light-emitting region LAG includes the green wavelength converting layer 48G instead of the green light-emitting layer 10G. For example, the green light-emitting region LAG of the wavelength converting layer 48 according to this embodiment includes: the green wavelength converting layer 48G; and the green first outer edge region 16G positioned on a side surface that is at least a portion of the green wavelength converting layer 48G. Furthermore, the green wavelength converting layer 48G includes the same main light-emitting materials as those of the green light-emitting layer 10G according to any of the above-described embodiments.

The blue light-emitting region LAB of the wavelength converting layer 48 according to this embodiment is the same in configuration as the blue light-emitting region LAB of the light-emitting layer 10 according to any of the above-described embodiments except that the former blue light-emitting region LAB includes the blue wavelength converting layer 48B instead of the blue light-emitting layer 10B. The blue wavelength converting layer 48B includes the same main light-emitting materials as those of the blue light-emitting layer 10B according to any of the above-described embodiments.

Note that the bank 14 according to this embodiment is the same in configuration as the bank 14 according to each of the above-described embodiments. For example, in plan view, the bank 14 according to this embodiment is formed in a position across a boundary between subpixels adjacent to each other. Furthermore, the wavelength converting layer 48 has the non-light-emitting region NLA including a first outer edge region. In plan view, the first outer edge region is provided in a position overlapping with the bank 14. The bank 14 according to this embodiment is formed of the same material as that of the bank 14 according to each of the above-described embodiments.

In this embodiment, the light source unit 46 may individually emit light to each of the light-emitting regions of the wavelength converting layer 48. For example, the light source unit 46 may include a light-emitting element provided for each of the subpixels and emitting ultraviolet light. The light-emitting element may be controlled for each subpixel. Alternatively, the light source unit 46 may include: a backlight unit that emits ultraviolet light; and a liquid crystal element formed on the backlight unit and controlling, for each subpixel, the amount of light emitted from the backlight unit to the wavelength converting layer.

The wavelength converting layer 48 according to this embodiment includes a main region and a first outer edge region each containing quantum dots coordinated with different ligands. Hence, the display device 44 according to this embodiment can more efficiently provide the first outer edge region, included in the light-emitting region of the wavelength converting layer 48, with a function different from that of the main region of the light-emitting region, depending on the difference in the contained ligands.

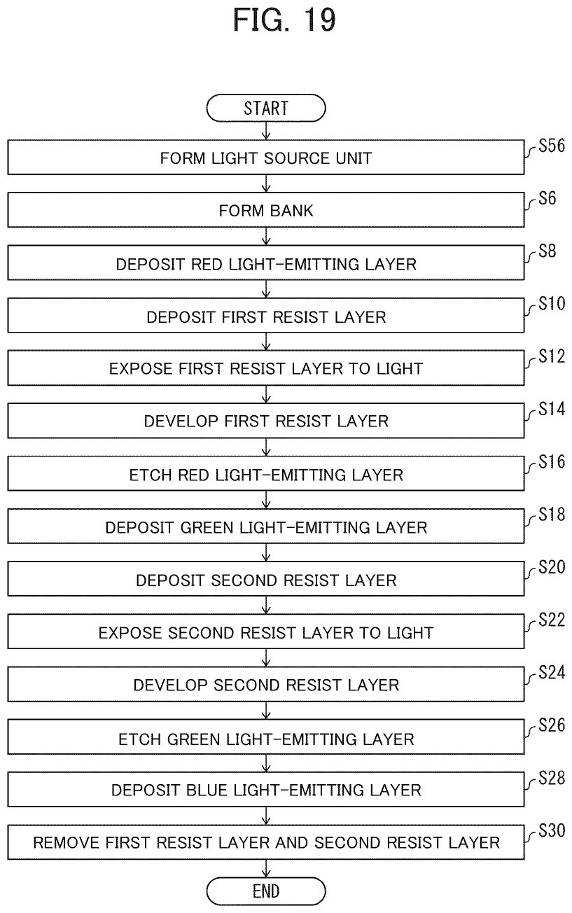

A method of producing the display device 44 according to this embodiment will be described, with reference to FIG. 19. FIG. 19 is a flowchart showing the method of producing the display device 44 according to this embodiment.

In the method of producing the display device 44 according to this embodiment, first, the light source unit 46 is formed (Step S56). The light source unit 46 may include a light-emitting element positioned in association with each of the subpixels of the display device 44. The light-emitting element may be formed by a known technique to emit ultraviolet light. Alternatively, the light source unit 46 may include a liquid crystal element formed on a backlight unit that emits ultralight light, and positioned in association with each of the subpixels of the display device 44. The liquid crystal element may be formed by a know technique.

In the method of producing the display device 44 according to this embodiment, the bank 14 is formed following the formation of the light source unit 46 (Step S6). The bank 14 according to this embodiment is made of the same material, and formed in the same position, as the bank 14 according to each of the previous embodiments is. Hence, the bank 14 according to this embodiment can be produced by the same technique employed at Step S6 according to each of the previous embodiments.

Next, the wavelength converting layer 48 is produced. Here, as described above, the wavelength converting layer 48 according to this embodiment is the same in configuration as the light-emitting layer 10 according to each of the previous embodiments. Hence, the wavelength converting layer 48 according to this embodiment can be produced by the same technique employed for the light-emitting layer 10 according to each of the previous embodiments. For example, as shown in FIG. 19, Step S6 is carried out. After that, Steps S8 to S30 of the method of producing the display device 2 according to the first embodiment are sequentially carried out to produce the wavelength converting layer 48 instead of the light-emitting layer 10. Hence, the wavelength converting layer 48 according to this embodiment is successfully formed. This is how the production of the display device 44 according to this embodiment is completed.

As can be seen, the wavelength converting layer 48 according to this embodiment can be produced by the same technique employed for the light-emitting layer 10 according to each of the previous embodiments. Hence, also in this embodiment, the red light-emitting region LAR can be formed at a step of etching, using a resist layer to be used for patterning other light-emitting regions. Thanks to the step, the method of producing the display device 44 according to this embodiment can be implemented with fewer steps required.

For example, in the display device 44 according to this embodiment, the bank 14 may be formed of a transparent material. Alternatively, the display device 44 may omit the bank 14.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

For example, each of the above embodiments describes a case where the functional layer is mainly a light-emitting layer. However, in each of the above-described embodiments, the functional layer may be a charge transport layer, and the charge transport layer may contain nanoparticles. Furthermore, in each of the above-described embodiments, the charge transport layer may have: a main region containing main ligands; and an outer edge region formed on an outer edge of the charge transport layer and containing outer edge ligands. Moreover, in each of the above-described embodiments, both the light-emitting layer and the charge transport layer may have: a main region at least partially containing main ligands; and an outer edge region containing outer edge ligands. Only the charge transport layer may have the main region and the outer edge region.

In addition, each of the above embodiments describes a case where the electronic device is a display device. However, in each of the above-described embodiments, an electronic device other than the display device may have a functional layer containing nanoparticles. In such a case, in each of the above-described embodiments, the functional layer may have: a main region containing main ligands; and an outer edge region formed on an outer edge of the functional layer and containing outer edge ligands. The outer edge ligands may be different in configuration from the main ligands.

Furthermore, the main region does not have to contain ligands. For example, if the charge transport layer serving as a functional layer contains nanoparticles including ZnO, NiO, or CuO in the main region, these nanoparticles do not have to be coordinated with ligands. Note that the presence or absence of the ligands in the functional layer can be confirmed, for example, by spectral spectroscopy using a Fourier transform infrared spectrophotometer (FT-IR). For example, when the functional layer containing no ligands is subjected to spectral spectroscopy using a FT-IR as described above, absorption of light having a specific wavelength is not observed. The absorption is derived from an organic substance contained in the ligands. Moreover, if the main region does not contain ligands, a functional layer not containing the ligands is deposited at the functional layer depositing step.

Examples of the electronic device other than the display device include photosensors, solar cells, or transistors, all of which include, for example, nanoparticle materials.

In addition, each of the above embodiments describes a case where, nanoparticles (e.g., the quantum dots) are coordinated with ligands. However, in each of the above-described embodiments, the electronic device may have ligands not coordinated to the nanoparticles contained in the functional layer. Furthermore, the ligands may be coordinated in different states between the main region and the outer edge region.

In addition, in each of the above-described embodiments, the functional layer is formed mainly by lift-off. Alternatively, for the electronic device, the functional layer may be formed by a technique other than lift-off to include a main region and an outer edge region.

1. An electronic device, comprising
a functional layer containing nanoparticles,
wherein the functional layer has: an outer edge region formed on an outer edge of the functional layer and containing outer edge ligands; and a main region internally in contact with the outer edge region, and
the outer edge ligands per unit volume contained in the outer edge region are greater in amount than the outer edge ligands per unit volume in the main region.

2. The electronic device according to claim 1,
wherein the main region contains main ligands different from the outer edge ligands, and
the main ligands per unit volume contained in the main region are greater in amount than the main ligands per unit volume in the outer edge region.

3. The electronic device according to claim 1,
wherein the main region does not contain any ligands.

4. The electronic device according to claim 1, further comprising
n kinds of ranges in which kinds of the nanoparticles contained are different from one another where n is a natural number of 2 or more, and
only (n−1) kinds of the ranges each include the main region and the outer edge region.

5. The electronic device according to claim 1, further comprising
n kinds of ranges in which kinds of the nanoparticles contained are different from one another where n is a natural number of 2 or more, and
only one kind of the ranges includes the main region and the outer edge region.

6. (canceled)

7. The electronic device according to claim 1,
wherein the outer edge ligands have polarity.

8. (canceled)

9. The electronic device according to claim 1,
wherein the outer edge ligands have non-polarity.

10. (canceled)

11. The electronic device according to claim 1,
wherein the nanoparticles are quantum dots.

12. The electronic device according to claim 11,
wherein the nanoparticles emit light by an exciton formed by recombination of electrons and holes, and
the electronic device includes:
a plurality of pixels each having a plurality of subpixels each including a light-emitting element;
a first electrode provided for each of the plurality of subpixels;
a second electrode provided in common to the plurality of subpixels; and
a light-emitting layer provided between the first electrode and the second electrode,
wherein the light-emitting layer includes at least one layer serving as the functional layer.

13. The electronic device according to claim 11,
wherein the nanoparticles are capable of transporting holes, and
the electronic device includes:
a plurality of pixels each having a plurality of subpixels each including a light-emitting element;
a first electrode provided for each of the plurality of subpixels;
a second electrode provided in common to the plurality of subpixels;
a light-emitting layer provided between the first electrode and the second electrode; and
a hole transport layer provided either between the first electrode and the light-emitting layer or between the second electrode and the light-emitting layer,
wherein the hole transport layer includes at least one layer serving as the functional layer.

14. The electronic device according to claim 11,
wherein the nanoparticles are capable of transporting electrons, and
the electronic device includes:
a plurality of pixels each having a plurality of subpixels each including a light-emitting element;
a first electrode provided for each of the plurality of subpixels;
a second electrode provided in common to the plurality of subpixels;
a light-emitting layer provided between the first electrode and the second electrode; and
an electron transport layer provided either between the first electrode and the light-emitting layer or between the second electrode and the light-emitting layer,
wherein the electron transport layer includes at least one layer serving as the functional layer.

15. The electronic device according to claim 11,
wherein the nanoparticles absorb light having a specific wavelength, and emit light having a wavelength different from the specific wavelength, and
the electronic device includes:
a plurality of pixels each having a plurality of subpixels;
a wavelength converting layer provided for each of the plurality of subpixels; and
a light source unit configured to emit light to the wavelength converting layer,
wherein the wavelength converting layer includes at least one layer serving as the functional layer.

16-21. (canceled)

22. A method of producing an electronic device, the method comprising:
a first functional layer depositing step of depositing a first functional layer containing first nanoparticles;
a first resist layer depositing step of depositing a first resist layer above the first functional layer;
a first light exposure step of exposing the first resist layer with light;
a first developing step of developing the first resist layer to remove a portion of the first resist layer; and
a first etching step of partially etching a surface of the first functional layer from toward the first resist layer to introduce first outer edge ligands to form a first outer edge region on an outer edge that is at least a portion of the first functional layer, the first outer edge region having the first outer edge ligands and the first nanoparticles.

23. The method of producing the electronic device according to claim 22,
wherein the first functional layer deposited at the first functional layer depositing step contains first main ligands different from the first outer edge ligands, and
at the first etching step, the first main ligands are substituted with the first outer edge ligands.

24. The method of producing the electronic device according to claim 22,
wherein the first functional layer deposited at the first functional layer depositing step does not contain any ligands.

25. The method of producing the electronic device according to claim 22,
wherein the first developing step and the first etching step are carried out simultaneously, or sequentially in this order, using a first etchant, and
the first etchant contains: a resist dissolving component to dissolve the first resist layer exposed to light; the first outer edge ligands; and a solvent in which a solute containing the first outer edge ligands dissolves.

26. The method of producing the electronic device according to claim 22,
wherein the first etching step is carried out using a first etchant,
the first etchant contains: the first outer edge ligands; and a solvent in which a solute containing the first outer edge ligands dissolves.

27. The method of producing the electronic device according to claim 25, further comprising
a second functional layer depositing step of depositing, after the first etching step, a second functional layer containing second nanoparticles different from the first nanoparticles.

28-30. (canceled)

31. The method of producing the electronic device according to claim 25,
wherein the first etchant is a solution a solvent of which contains a solute containing at least one selected from the group consisting of tetramethylammonium hydroxide, 2-aminoethanethiol hydrochloride, 2-methaneaminoethanethiol hydrochloride, 2-ethaneaminoethanethiol hydrochloride, 2-dimethylaminoethanethiol hydrochloride, 2-methylethylaminoethanethiol hydrochloride, and 2-diethylaminoethanethiol hydrochloride.

32. (canceled)

33. The method of producing the electronic device according to claim 25,
wherein the first etchant is a solution a solvent of which contains a solute containing, as a coordinating functional group, at least one selected from the group consisting of a thiol group, an amino group, a carboxyl group, a phosphonic group, a phosphine group, and a phosphine oxide group.

34-37. (canceled)
